(19) United States
(12) Patent Application Publication
(10) Pub. No.: US 2025/0113542 A1
(43) Pub. Date: Apr. 3, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Kentaro MIURA, Tokyo (JP); Akihiro HANADA, Tokyo (JP); Takaya TAMARU, Tokyo (JP); Masahiro WATABE, Tokyo (JP)

(73) Assignee: Japan Display Inc., Tokyo (JP)

(21) Appl. No.: 18/887,091

(22) Filed: Sep. 17, 2024

(30) Foreign Application Priority Data
Sep. 29, 2023 (JP) 2023-169684

(51) Int. Cl. H01L 29/786

(52) U.S. Cl. CPC H10D 30/6755; H10D 30/6715

(57) ABSTRACT

A semiconductor device comprises a first insulating layer; an oxide semiconductor layer having a polycrystalline structure on the first insulating layer; a gate insulating layer on the semiconductor oxide layer; a buffer layer on the gate insulating layer; a gate wiring on the buffer layer; and a second insulating layer on the gate wiring. The oxide semiconductor layer has a first region, a second region and a third region aligned toward a first direction. An electrical resistivity of the second region is higher than an electrical resistivity of the first region and lower than an electrical resistivity of the third region. A sheet resistance of the third region is less than 1000 ohm/square.

### CROSS REFERENCE TO RELATED APPLICATIONS

This application claims the benefit of priority to Japanese Patent Application No. 2023-169684, filed on Sep. 29, 2023, the entire contents of which are incorporated herein by reference.

### FIELD

An embodiment of the present invention relates to a semiconductor device. In particular, an embodiment of the present invention relates to a semiconductor device containing an oxide semiconductor.

### BACKGROUND

In recent years, an oxide semiconductor, instead of amorphous silicon, polysilicon, and single-crystal silicon, has attracted attention as a constituent material of a semiconductor device. In particular, a thin film transistor using an oxide semiconductor as a channel has been developed as a semiconductor device containing an oxide semiconductor (see, for example, Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). A thin film transistor using an oxide semiconductor as a channel can be formed in a simple-structure and low-temperature process, similar to a semiconductor device using amorphous silicon as a channel. The thin film transistor using an oxide semiconductor as a channel is known to have higher field-effect mobility than the thin film transistor using amorphous silicon as a channel.

### SUMMARY

A semiconductor device according to an embodiment of the invention comprises a first insulating layer; an oxide semiconductor layer having a polycrystalline structure on the first insulating layer; a gate insulating layer on the semiconductor oxide layer; a buffer layer on the gate insulating layer; a gate wiring on the buffer layer; and a second insulating layer on the gate wiring. The oxide semiconductor layer has a first region, a second region and a third region aligned toward a first direction. An electrical resistivity of the second region is higher than an electrical resistivity of the first region and lower than an electrical resistivity of the third region. A sheet resistance of the third region is less than 1000 ohm/square.

A semiconductor device according to an embodiment of the invention comprises a first insulating layer; an oxide semiconductor layer having a polycrystalline structure on the first insulating layer; a gate insulating layer on the semiconductor oxide layer; a buffer layer on the gate insulating layer; a gate wiring on the buffer layer; and a second insulating layer on the gate wiring. The oxide semiconductor layer has a first region, a second region and a third region aligned toward a first direction. An electrical resistivity of the second region is higher than an electrical resistivity of the first region and lower than an electrical resistivity of the third region. An etching rate is less than 3 nm/min when the oxide semiconductor layer is etched using an etching solution containing phosphoric acid as the main component at 40° C.

### BRIEF DESCRIPTION OF THE DRAWINGS

FIG. 1 is a schematic cross-sectional view showing a configuration of a semiconductor device according to an embodiment of the present invention.

FIG. 2 is a schematic plan view showing a configuration of a semiconductor device according to an embodiment of the present invention.

FIG. 3 is an enlarged cross-sectional view showing a configuration of a semiconductor device according to an embodiment of the present invention.

FIG. 4 is a sequence diagram showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a cross-sectional view showing a method for manufacturing a semiconductor device according to an embodiment of the present invention.

FIG. 19 is a cross-sectional view showing a method for manufacturing a semiconductor device according to an embodiment of the present invention.

FIG. 20 is a cross-sectional view showing a method for manufacturing a semiconductor device according to an embodiment of the present invention.

FIG. 21 is a cross-sectional view showing a method for manufacturing a semiconductor device according to an embodiment of the present invention.

FIG. 22 is a cross-sectional view showing a method for manufacturing a semiconductor device according to an embodiment of the present invention.

FIG. 23 is a cross-sectional view showing a method for manufacturing a semiconductor device according to an embodiment of the present invention.

FIG. 24 is a cross-sectional view showing a method for manufacturing a semiconductor device according to an embodiment of the present invention.

FIG. 25 is a cross-sectional view showing a configuration of a semiconductor device according to an embodiment of the present invention.

FIG. 26 is a schematic plan view showing a configuration of an entire display device according to an embodiment of the present invention.

FIG. 27 is a block diagram showing a circuit configuration of a display device according to an embodiment of the present invention.

FIG. 28 is a circuit diagram showing a pixel circuit of a display device according to an embodiment of the present invention.

### DESCRIPTION OF EMBODIMENTS

A thin film transistor using a conventional oxide semiconductor may deteriorate due to the application of a high-voltage between a source and a drain, similar to a thin film transistor using a silicon semiconductor. Such deterioration may lead to reduced reliability, such as a shift in a threshold voltage.

An object of the present invention is to improve the reliability of a semiconductor device including an oxide semiconductor.

Hereinafter, embodiments of the present invention will be described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the width, thickness, shape, and the like of each part in comparison with an actual embodiment. However, the illustrated shapes are merely examples, and do not limit the interpretation of the present invention. In the present specification and the drawings, the same reference signs are given to elements similar to those described above with respect to the above-described drawings, and detailed description thereof may be omitted as appropriate.

In the embodiments of the present invention, a direction from a substrate toward an oxide semiconductor layer is referred to as on or above. Conversely, a direction from the oxide semiconductor layer to the substrate is referred to as under or below. In this way, for convenience of explanation, the phrase “above” or “below” is used for description, but for example, the substrate and the oxide semiconductor layer may be arranged so that the upper and lower relationship is opposite to those shown in the drawings. In the following explanation, for example, the expression “oxide semiconductor layer on substrate” merely describes the upper and lower relationship between the substrate and the oxide semiconductor layer as described above, and another member may be arranged between the substrate and the oxide semiconductor layer. Above and below refer to a stacking order in which a plurality of layers is stacked, and may be a positional relationship in which the transistor does not overlap a pixel electrode in a plan view when expressed as “pixel electrode above a transistor”. On the other hand, the expression “pixel electrode vertically above a transistor” means a positional relationship in which the transistor overlaps the pixel electrode in a plan view.

“Display device” refers to a structure that displays an image using an electro-optical layer. For example, the term display device may refer to a display panel that includes the electro-optical layer, or may refer to a structure with other optical members (for example, a polarized member, a backlight, a touch panel, and the like) attached to a display cell. “Electro-optical layer” may include a liquid crystal layer, an electroluminescent (EL) layer, an electrochromic (EC) layer, and an electrophoretic layer, unless there is no technical contradiction. Therefore, a liquid crystal display device including a liquid crystal layer and an organic EL display device including an organic EL layer will be exemplified as a display device in the embodiment described later, but the structure according to the embodiment can be applied to a display device including other electro-optical layers described above.

In the present specification, the expressions “a includes A, B or C,” “α includes any of A, B and C,” “αincludes one selected from a group consisting of A, B, and C,” and the like do not exclude case where α includes a plurality of combinations of A to C unless otherwise specified. Furthermore, these expressions do not exclude the case where a includes other elements.

In the present specification, “identical” includes, in addition to being completely identical, also the case of being substantially identical. “Substantially identical” refers to the case that falls within a range of small differences that are not completely identical but can be regarded as identical, for example, within an error of ±5% (preferably ±3%).

### First Embodiment

A semiconductor device according to an embodiment of the present invention will be described using a thin film transistor as an example. For example, the semiconductor device of the embodiment shown below may be an integrated circuit (IC) such as a micro-processing unit (MPU) or a thin film transistor used in a memory circuit, in addition to the thin film transistor used in the display device.

### [Configuration of Semiconductor Device]

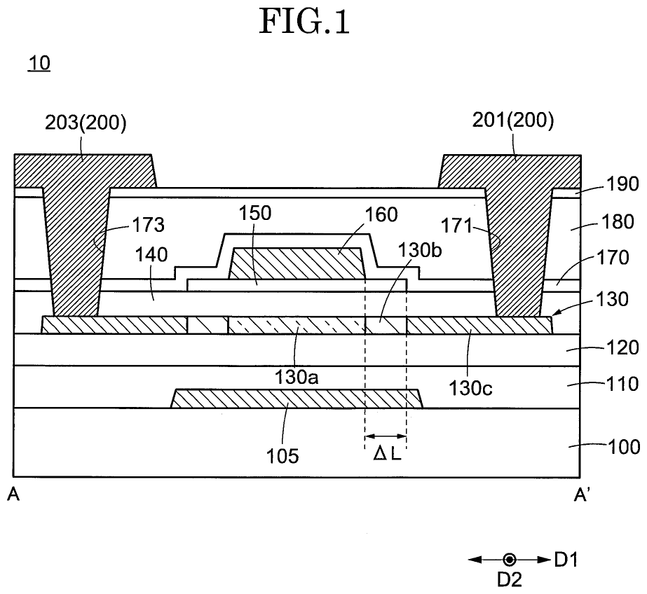

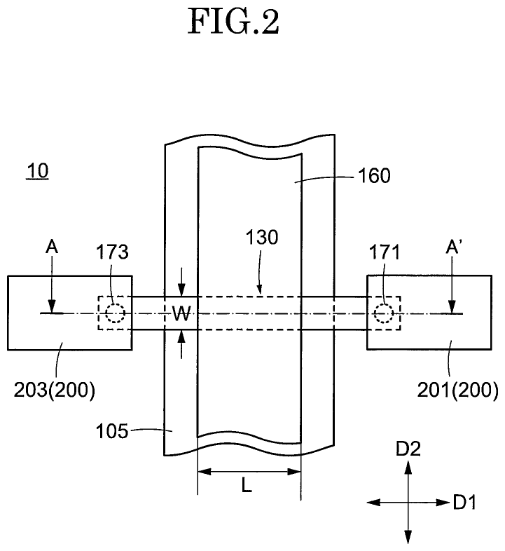

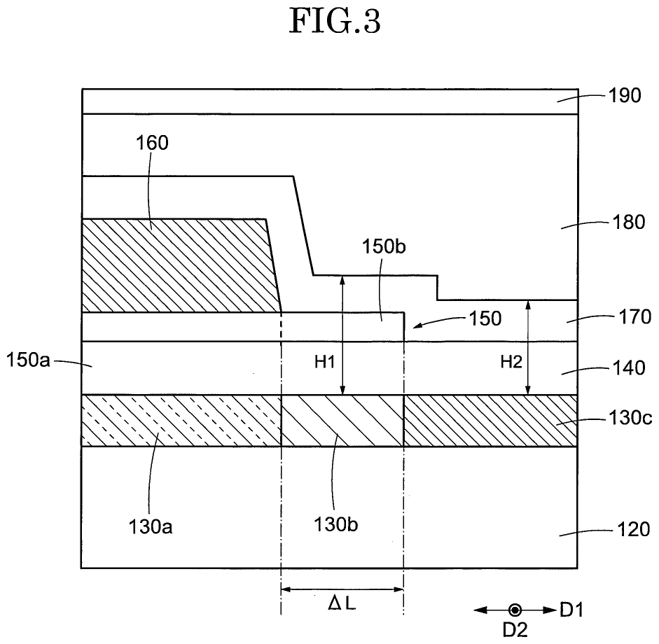

A configuration of a semiconductor device 10 according to an embodiment of the present invention will be described. FIG. 1 is a schematic cross-sectional view showing a configuration of the semiconductor device 10 according to an embodiment of the present invention. FIG. 2 is a schematic plan view showing a configuration of the semiconductor device 10 according to an embodiment of the present invention. FIG. 3 is a schematic enlarged cross-sectional view showing a configuration of the semiconductor device 10 according to an embodiment of the present invention. Specifically, FIG. 1 corresponds to a cross-sectional view cut along a dashed-dotted line indicated by A-A′ shown in FIG. 2. FIG. 3 corresponds to an enlarged cross-sectional view near an end portion of a gate wiring 160 shown in FIG. 1.

First, a cross-sectional structure of the semiconductor device 10 will be described with reference to FIG. 1. As shown in FIG. 1, the semiconductor device 10 is arranged above a substrate 100. The semiconductor device 10 includes a conductive layer 105, insulating layers 110 and 120, an oxide semiconductor layer 130, a gate insulating layer 140, a buffer layer 150, a gate wiring 160, insulating layers 170 to 190, a source wiring 201, and a drain wiring 203. In the case where the source wiring 201 and the drain wiring 203 are not specifically distinguished from each other, they may be collectively referred to as a source/drain wiring 200.

In the present specification, “wiring” refers to a conductive layer that electrically connects between elements, circuits, or between an element and a circuit. The wiring may also function as an electrode. For example, part of the gate wiring 160 that overlaps the oxide semiconductor layer 130 functions as a gate electrode. In addition, part of the source wiring 201 and the drain wiring connected to the oxide semiconductor layer 130 functions as a source electrode and a drain electrode, respectively.

The conductive layer 105 is arranged on the substrate 100. The conductive layer 105 has a function as a light-shielding film for the oxide semiconductor layer 130.

The insulating layers 110 and 120 are arranged on the substrate 100 and the conductive layer 105. The insulating layer 110 functions as a barrier film that shields impurities that diffuse from the substrate 100 toward the oxide semiconductor layer 130. The insulating layer 120 functions as a base of the oxide semiconductor layer 130 arranged above.

The oxide semiconductor layer 130 is arranged on the insulating layer 120. The oxide semiconductor layer 130 has a channel region 130a, an LDD region 130b, and a conductive region 130c aligned in a first direction. The channel region 130a is a region of the oxide semiconductor layer 130 that overlaps the gate wiring 160, and functions as a channel of the transistor. The LDD region 130b is a region having a lower resistance than the channel region and functions as a resistance component against carrier movement. The conductive region 130c is a region called a source region or drain region and functions as a conductive layer connected to the source wiring 201 or the drain wiring 203. The conductive region 130c is a region having a lower resistance than the LDD region 130b. Although details will be described later, the LDD region 130b acts as a resistance component against carrier movement.

The gate insulating layer 140 is arranged on the oxide semiconductor layer 130. The gate insulating layer 140 is a dielectric layer arranged between the oxide semiconductor layer 130 and the gate wiring 160. Although a silicon oxide layer is used as the gate insulating layer 140 in the present embodiment, the present invention is not limited to this.

The buffer layer 150 is arranged on the gate insulating layer 140. Although details will be described later, the buffer layer 150 is used as a layer having a function of suppressing implantation of impurities into the oxide semiconductor layer 130 or a function of suppressing hydrogen-diffusion into the oxide semiconductor layer 130. The buffer layer 150 is removed by etching leaving a part around the gate wiring 160. Therefore, part of the gate insulating layer 140 is not covered with the buffer layer 150 and is exposed from the buffer layer 150. In addition, a metal material such as titanium can be used as a metal. As will be described later, the buffer layer 150 preferably functions as an etching stopper when etching the gate wiring 160. That is, the selectivity between the buffer layer 150 and the gate wiring 160 is preferably high. Although a silicon oxide layer is used as the buffer layer 150 in the present embodiment, the present invention is not limited to this.

The buffer layer 150 includes a region that overlaps the gate wiring 160 (an overlapping region 150a in FIG. 3) and a region that does not overlap the gate wiring 160 (a non-overlapping region 150b in FIG. 3). That is, a width of the buffer layer 150 in the first direction (direction D1) is wider than a width of the gate wiring 160. This will be described later with reference to FIG. 3. The LDD region 130b of the oxide semiconductor layer 130 is a region positioned vertically below the non-overlapping region 150b of the buffer layer 150 described above. In the embodiment shown in FIG. 1, a length (width) of the LDD region 130b in the first direction is ΔL.

The gate wiring 160 faces the oxide semiconductor layer 130 via the gate insulating layer 140 and the buffer layer 150. That is, the gate insulating layer 140 and the buffer layer 150 are arranged between the oxide semiconductor layer 130 and the gate wiring 160. The gate insulating layer 140 is in contact with the oxide semiconductor layer 130. The buffer layer 150 is in contact with the gate wiring 160. The gate wiring 160 has a function as a light-shielding film for a top gate and the oxide semiconductor layer 130 of the semiconductor device 10.

Although a side surface of the gate wiring 160 is inclined in the present embodiment, the present invention is not limited to this. However, making the side surface of the gate wiring 160 inclined to have a tapered shape makes it possible to reduce the occurrence of cracks in the insulating layer 170 formed on the gate wiring 160 and the poor coverage of the insulating layer 170.

The insulating layers 170 to 190 are arranged on the gate insulating layer 140, the buffer layer 150, and the gate wiring 160. In the present embodiment, a stacked structure composed of the insulating layers 170 to 190 may be referred to as a passivation layer. The insulating layers 170 to 190 insulate the gate wiring 160 and the source/drain wiring 200. Arranging the insulating layers 170 to 190 makes it possible to reduce the parasitic capacitance between the gate wiring 160 and the source/drain wiring 200.

In the present embodiment, a silicon oxide layer, a silicon nitride layer, and a silicon oxide layer are used as the insulating layer 170, an insulating layer 180, and the insulating layer 190, respectively. Materials of the insulating layers 170 to 190 are not limited to the example, but preferably include at least one insulating layer containing hydrogen, as described below. Furthermore, in the present embodiment, a silicon oxide layer is used as the insulating layer 190 so as to function as an etching stopper when patterning the source wiring 201 and the drain wiring 203.

As shown in FIG. 1, the insulating layer 170 forming part of the passivation layer is in contact with the gate wiring 160, the buffer layer 150 (specifically, a region of the buffer layer 150 that does not overlap the gate wiring 160), and the gate insulating layer 140. Contact holes 171 and 173 that reach the oxide semiconductor layer 130 are arranged in the insulating layers 170 to 190 and the gate insulating layer 140.

The source wiring 201 is arranged inside the contact hole 171 arranged in the insulating layers 170 to 190 and the gate insulating layer 140. The source wiring 201 is in contact with the oxide semiconductor layer 130 (specifically, the conductive region 130c) at the bottom of the contact hole 171. The drain wiring 203 is arranged inside the contact hole 173 arranged in the insulating layers 170 to 190 and the gate insulating layer 140. The drain wiring 203 is in contact with the oxide semiconductor layer 130 (specifically, the conductive region 130c) at the bottom of the contact hole 173.

The operation of the semiconductor device 10 is controlled mainly by a gate voltage supplied to the gate wiring 160. An auxiliary voltage may be supplied to the conductive layer 105. That is, the conductive layer 105 may function as a gate wiring by supplying the auxiliary voltage. However, the present embodiment is not limited to this, and the conductive layer 105 may be used merely as a light-shielding film. In the case where the conductive layer 105 is simply used as a light-shielding film, the conductive layer 105 may be in a floating state without being supplied with a specific voltage.

Although a top-gate transistor in which the gate wiring 160 is arranged above the oxide semiconductor layer 130 is exemplified as the semiconductor device 10 in the present embodiment, the configuration is not limited to this. For example, in addition to the gate wiring 160, a dual-gate transistor using the conductive layer 105 as the gate wiring can be used as the semiconductor device 10. In the case where the conductive layer 105 is used as a gate wiring, the insulating layers 110 and 120 function as a gate insulating layer. However, the above configuration is merely an embodiment, and the present invention is not limited to the above configuration.

Next, a planar structure of the semiconductor device 10 will be described with reference to FIG. 2. As shown in FIG. 2, the first direction (direction D1) is a direction connecting the source wiring 201 and the drain wiring 203, and corresponds to a direction in which a carrier moves. A length of the oxide semiconductor layer 130 in the first direction of the channel region 130a is a channel length (L), and a length of the channel region 130a in a second direction (direction D2) is a channel width (W). In addition, the second direction is a direction intersecting the first direction. Although the second direction indicates a direction orthogonal to the first direction in the present embodiment, the first direction and the second direction may not be orthogonal depending on the layout of the oxide semiconductor layer 130.

In the present embodiment, a width of the conductive layer 105 is wider than a width of the gate wiring 160 in the first direction. The reason for this configuration is to effectively prevent external light from entering the channel region 130a. However, the width of the conductive layer 105 may be the same as the width of the gate wiring 160.

Although a configuration in which the source/drain wiring 200 does not overlap the gate wiring 160 and the conductive layer 105 in a plan view is exemplified in FIG. 2, the present invention is not limited to this configuration. For example, in a plan view, the source/drain wiring 200 may overlap at least one of the conductive layer 105 and the gate wiring 160. The above configuration is merely an embodiment, and the present invention is not limited to the above configuration.

### [Materials of Each Layer of Semiconductor Device]

The substrate 100 may support each layer constituting the semiconductor device 10. For example, a rigid substrate having light transmittance such as a glass substrate, a quartz substrate, or a sapphire substrate can be used as the substrate 100. In addition, a rigid substrate having no light transmittance such as a silicone substrate can also be used as the substrate. Furthermore, a flexible substrate having light transmittance such as a polyimide resin substrate, an acryl resin substrate, a siloxane resin substrate, or a fluororesin substrate can be used as the substrate. In order to improve the heat resistance of the substrate 100, impurities may be introduced into the resin substrate. In addition, a substrate in which a silicon oxide film or silicon nitride film is formed on the above-described rigid substrate or flexible substrate can also be used as the substrate 100.

The conductive layer 105 may reflect or absorb external light. As described above, since the conductive layer 105 has an area larger than the channel region 130a of the oxide semiconductor layer 130, external light incident on the channel region 130a can be shielded. For example, aluminum (Al), copper (Cu), titanium (Ti), molybdenum (Mo), or tungsten (W), or an alloy or a compound thereof can be used as the conductive layer 105. Furthermore, in the case where no electrical conductivity is required, a resin layer made of a black plastic, or the like may be used instead of the conductive layer 105. The conductive layer 105 may have a single-layer structure or stacked structure.

The insulating layers 110, 120, and 170 to 190 have a function to prevent impurities from diffusing into the oxide semiconductor layer 130. The insulating layers 110, 120, and 170 to 190 may be a single-layer structure or stacked structure. Examples of the insulating layers 110, 120, and 170 to 190 include silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), and aluminum nitride (AlNₓ). In this case, silicon oxynitride (SiOₓN_{y}) and aluminum oxynitride (AlOₓN_{y}) are a silicon compound and aluminum compound containing a smaller proportion (x>y) of nitrogen (N) than oxygen (O), respectively. In addition, silicon nitride oxide (SiNₓO_{y}) and aluminum nitride oxide (AlNₓO_{y}) are a silicon compound and aluminum compound containing a smaller proportion (x>y) of oxygen than nitrogen. In the present embodiment, silicon nitride (SiNₓ) is used as the insulating layers 110 and 180, and silicon oxide (SiOₓ) is used as the insulating layers 120, 170, and 190.

In the present embodiment, the oxide semiconductor layer 130 has a polycrystalline structure. That is, the oxide semiconductor layer 130 of the present embodiment is made of an oxide semiconductor formed using a Poly-OS technique. The Poly-OS technique refers to a technique of forming an oxide semiconductor layer having a polycrystalline structure. A metal oxide having semiconducting properties can be used as the oxide semiconductor layer 130. For example, an oxide semiconductor containing two or more metals including indium (In) is used as the oxide semiconductor layer 130. Elements other than those described above may be used as the oxide semiconductor layer 130. For example, gallium (Ga), zinc (Zn), aluminum (Al), hafnium (Hf), yttrium (Y), zirconia (Zr), and lanthanoids may be used as the oxide semiconductor layer 130 in addition to indium.

The ratio of indium to the entire oxide semiconductor layer 130 is preferably 50% or more. When the ratio of indium increases, the oxide semiconductor layer 130 is more likely to crystallize. In addition, it is preferable to contain gallium as a metal element other than indium. Gallium belongs to the same Group 13 element as indium. Therefore, the crystallinity of the oxide semiconductor layer 130 is hardly inhibited by gallium.

Since the proportion of indium is 50% or more in the oxide semiconductor layer 130 of the present embodiment, oxygen deficiencies are likely to be formed. On the other hand, the oxide semiconductor having crystallinity is less likely to form oxygen deficiencies than the amorphous oxide semiconductor. Therefore, the oxide semiconductor layer 130 has an advantage that oxygen deficiencies are hardly formed even though the proportion of indium is 50% or more.

The gate insulating layer 140 includes an oxide having insulating properties. Specifically, silicon oxide (SiOₓ), silicon oxynitride (SiOₓN_{y}), aluminum oxide (AlOₓ), aluminum oxynitride (AlOₓN_{xy}), or the like can be used as the gate insulating layer 140. The gate insulating layer 140 preferably has a composition close to the stoichiometric ratio. In addition, the gate insulating layer 140 is preferably less defective. For example, an oxide in which no defects are observed when evaluated by an electron-spin resonance method (ESR) may be used as the gate insulating layer 140. In the present embodiment, a silicon oxide layer having a thickness of 100 nm or more and 200 nm or less is used as the gate insulating layer 140.

An oxide or metal having insulating or conductive properties can be used as the buffer layer 150. The buffer layer 150 may be a layer having a function of suppressing implantation of impurities into the oxide semiconductor layer 130 or a function of suppressing hydrogen-diffusion into the oxide semiconductor layer 130. For example, a thickness of the buffer layer 150 may be 5 nm or more and 100 nm or less. That is, the thickness of the buffer layer 150 may be smaller than a thickness of the gate insulating layer 140.

In the case where the buffer layer 150 is an insulating layer, the buffer layer 150 functions as part of the gate insulating layer because it is positioned between the oxide semiconductor layer 130 and the gate wiring 160. Therefore, when determining a device parameter of the semiconductor device 10, the thickness and the dielectric constant of the gate insulating layer 140 and the buffer layer 150 must be considered.

Silicon oxide (SiOₓ), silicon nitride (SiNₓ), silicon oxynitride (SiOₓN_{y}), silicon nitride oxide (SiOₓN_{y}), oxide semiconductor (OS), or a metal can be used as a material constituting the buffer layer 150. For example, a metal oxide such as IGZO can be used as the oxide semiconductor. In addition, a metal material such as titanium can be used as the metal.

The gate wiring 160, the source wiring 201, and the drain wiring 203 are electrically conductive. For example, copper (Cu), silver (Ag), aluminum (Al), titanium (Ti), chromium (Cr), cobalt (Co), nickel (Ni), molybdenum (Mo), hafnium (Hf), tantalum (Ta), tungsten (W), or bismuth (Bi), or an alloy or compound thereof can be used as each of the gate wiring 160, the source wiring 201, and the drain wiring 203. Each of the gate wiring 160, the source wiring 201, and the drain wiring 203 may be a single-layer structure or stacked structure.

### [Configuration in the Vicinity of End Portion of Gate Wiring]

A configuration in the vicinity of the end portion of the gate wiring 160 will be described with reference to FIG. 3. As shown in FIG. 3, the oxide semiconductor layer 130 is divided into the channel region 130a, the LDD region 130b, and the conductive region 130c. The channel region 130a is a region of the oxide semiconductor layer 130 that is positioned vertically below the gate wiring 160, that is, a region that overlaps the gate wiring 160. The conductive region 130c is a region of the oxide semiconductor layer 130 that does not overlap the buffer layer 150. The LDD region 130b is a region positioned between the channel region 130a and the conductive region 130c. Specifically, the LDD region 130b is a region that does not overlap the gate wiring 160 and overlaps the buffer layer 150.

As described above, the buffer layer 150 is divided into the overlapping region 150a that overlaps the gate wiring 160 and the overlapping region 150b that does not overlap the gate wiring 160. In other words, it can be said that the channel region 130a is a region positioned vertically below the overlapping region 150a. The LDD region 130b is a region positioned vertically below the non-overlapping region 150b.

As described above, in the oxide semiconductor layer 130 except for the channel region 130a, a region (the LDD region 130b) that overlaps both the gate insulating layer 140 and the buffer layer 150, and a region (the conductive region 130c) that overlaps the gate insulating layer 140 and does not overlap the buffer layer 150 are included. From another point of view, as shown in FIG. 3, a distance H1 from a top surface of the LDD region 130b to a top surface of the insulating layer 170 is longer than a distance H2 from a top surface of the conductive region 130c to a top surface of the insulating layer 170. In this case, the terms “distance H1” and “distance H2” refer to distances in a normal direction to the top surface of the oxide semiconductor layer 130.

As shown in FIG. 3, the gate insulating layer 140, the buffer layer 150 (specifically, the non-overlapping region 150b), and the insulating layer 170 are stacked above the LDD region 130b. Therefore, implantation of impurities into the oxide semiconductor layer 130 is suppressed in a process of reducing resistance of the oxide semiconductor layer 130 (a process of forming the conductive region 130c) using ion implantation described later. By suppressing the implantation of impurities, the LDD region 130b is formed between the channel region 130a and the conductive region 130c.

In addition, as shown in FIG. 3, a length (width) of the non-overlapping region 150b in the first direction corresponds to a length (width) of the LDD region 130b in the first direction. In FIG. 3, the length of the LDD region 130b in the first direction is represented as ΔL. The length of the non-overlapping region 150b in the first direction can be appropriately set during a patterning process of the buffer layer 150 described later.

In the present embodiment, the length of the non-overlapping region 150b in the first direction, that is, the length of the LDD region 130b in the first direction is not particularly limited. However, as described above, since the LDD region 130b functions as the resistance component against carrier movement, if it is too long, it may lead to degradation of the electrical characteristics of the semiconductor device 10. Therefore, the length of the LDD region 130b is preferably 1.5 μm or less (preferably 1.0 μm or less). In addition, the shorter the length of the LDD region 130b, the lower the drain breakdown voltage of the semiconductor device 10. Therefore, from the viewpoint of improving reliability, the length of the LDD region 130b is preferably 0.1 μm or more (preferably 0.3 μm or more, more preferably 0.5 μm or more).

According to the present embodiment, during the process of forming the conductive region 130c in the oxide semiconductor layer 130 (a process of reducing the resistance of the oxide semiconductor layer 130), the LDD region 130b having a lower resistance than that of the channel region 130a and a higher resistance than that of the conductive region 130c can be formed between the channel region 130a and the conductive region 130c. Since the LDD region 130b functions as the resistance component against carrier movement, the drain breakdown voltage of the semiconductor device 10 can be improved. That is, according to the present embodiment, the reliability of the semiconductor device 10 including the oxide semiconductor layer 130 can be improved.

### [Method for Manufacturing Semiconductor Device]

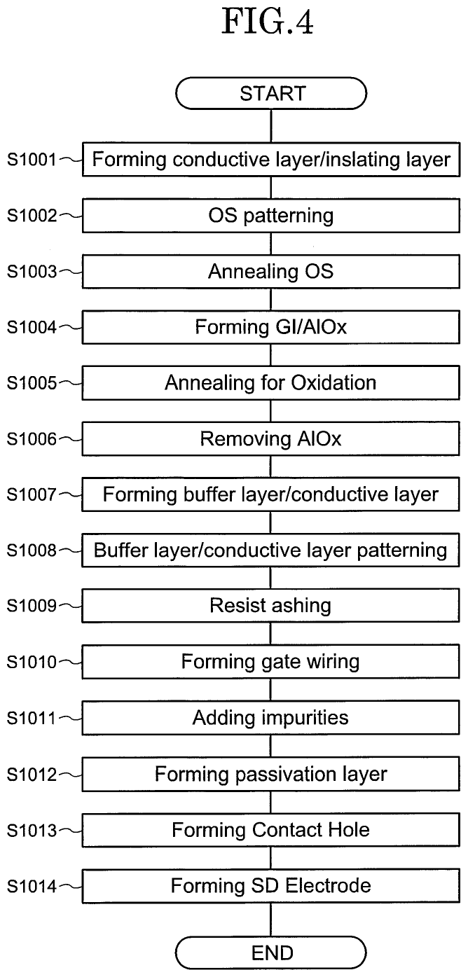

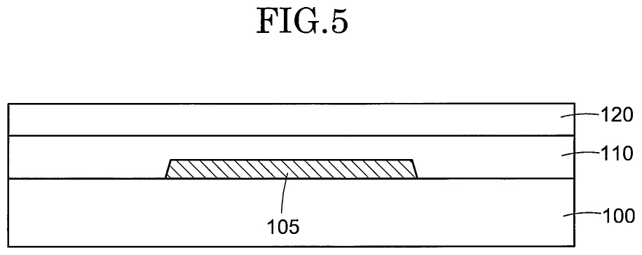

Next, a method for manufacturing the semiconductor device 10 according to an embodiment of the present invention will be described. FIG. 4 is a sequence diagram showing a method for manufacturing the semiconductor device 10 according to an embodiment of the present invention. FIG. 5 to FIG. 15 are schematic cross-sectional views showing a method for manufacturing the semiconductor device 10 according to an embodiment of the present invention.

As shown in FIG. 4 and FIG. 5, the conductive layer 105 is formed as a light-shielding layer on the substrate 100, and the insulating layers 110 and 120 are formed on the conductive layer 105 (step S1001 of FIG. 4). For example, a silicon nitride layer is formed as the insulating layer 110. For example, a silicon oxide layer is formed as the insulating layer 120. The insulating layers 110 and 120 are formed by a CVD (Chemical Vapor Deposition) method. In the present specification, performing film formation on the substrate by a method such as a sputtering method or a CVD method is expressed as “forming a thin film”, but is used in the same meaning as the expression “depositing a thin film”.

For example, using the silicon nitride layer as the insulating layer 110 makes it possible to block impurities diffusing from the substrate 100 toward the oxide semiconductor layer 130. The silicon oxide layer used as the insulating layer 120 may include silicon oxide having a physical property of releasing oxygen by a heat treatment.

In the present embodiment, the deposition temperature is set to 350° C. when forming the insulating layers 110 and 120. In particular, the insulating layer 120 (that is, the silicon oxide layer) can have a relatively low deposition temperature, thereby increasing the oxygen content. As will be described later, increasing the amount of oxygen contained in the insulating layer 120 makes it possible to reduce the amount of hydrogen diffused into the oxide semiconductor layer 130. In addition, the deposition temperature of the insulating layers 110 and 120 may be set to 250° C. or higher and 500° C. or lower (preferably 300° C. or higher and 450° C. or lower, and more preferably 325° C. or higher and 400° C. or lower).

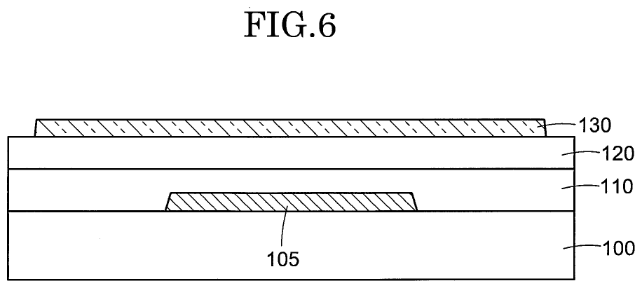

Next, as shown in FIG. 4 and FIG. 6, a patterned oxide semiconductor layer 130 is formed on the insulating layer 120 (step S1002 of FIG. 4). In the present embodiment, the process of forming the oxide semiconductor layer 130 is referred to as “OS patterning.” That is, the oxide semiconductor layer 130 is formed by performing a patterning treatment on the oxide semiconductor layer formed on the insulating layer 120. In the explanation of the present embodiment, the term “oxide semiconductor layer” without a reference sign refers to the oxide semiconductor layer in a deposited state (that is, in an unprocessed state).

Etching of the oxide semiconductor layer may be performed by wet etching or dry etching. For example, an acidic etchant (oxalic acid or hydrofluoric acid) can be used in the wet etching.

In the present embodiment, the oxide semiconductor layer is formed by a sputtering method. In particular, the oxide semiconductor layer is formed by sputtering using a target formed of the oxide semiconductor having crystallinity. As described above, the oxide semiconductor layer is composed of a metal oxide having an indium ratio of 50% or more. For example, the thickness of the oxide semiconductor layer to be deposited is 10 nm or more and 100 nm or less, 15 nm or more and 70 nm or less, or 15 nm or more and 40 nm or less. The oxide semiconductor layer of the present embodiment is amorphous in a deposited state. That is, the oxide semiconductor layer 130 (that is, the oxide semiconductor layer 130 immediately after patterning) before the heat treatment (OS annealing) described later is amorphous.

When the oxide semiconductor layer 130 is crystallized by OS annealing described later, the oxide semiconductor layer 130 after the formation by the sputtering method to before the OS annealing is preferably amorphous (a state in which the oxide semiconductor has few crystalline components). In other words, it is preferable that the oxide semiconductor layer is formed under a condition that the oxide semiconductor layer immediately after the deposition does not crystallize as much as possible. For example, in the case where the oxide semiconductor layer is formed by a sputtering method, it is desirable to form the oxide semiconductor layer while controlling the temperature of an object to be formed (including the substrate 100 and a structure formed thereon). In addition, the object to be temperature controlled is the object to be formed, but since the structure formed on the substrate 100 is very thin, it may be considered that the temperature of the substrate 100 is substantially controlled. Therefore, in the following explanation, the object to be formed may be simply referred to as “substrate”.

When a thin film formation (deposition) process is performed on the substrate by a sputtering method, ions generated in the plasma and atoms recoiled by a sputtering target collide with the object to be formed (specifically, the structure formed on the substrate 100), so that the temperature of the substrate increases in the process of forming the thin film. When the temperature of the substrate increases in the process of forming the thin film, the oxide semiconductor layer contains microcrystals in a state immediately after the formation, and crystallization due to subsequent OS annealing is inhibited.

In order to control the temperature (that is, the deposition temperature) of the substrate when forming the oxide semiconductor layer, for example, the thin film formation may be performed while cooling the substrate. For example, the substrate can be cooled from the other side of the surface to be formed so that the deposition temperature may be 100° C. or lower, 70° C. or lower, 50° C. or lower, or 30° C. or lower. In particular, the deposition temperature of the oxide semiconductor layer of the present embodiment is preferably 50° C. or lower. In the present embodiment, the oxide semiconductor layer is formed at a deposition temperature of 50° C. or lower, and the OS annealing, which will be described later, is performed at a heated temperature of 400° C. or higher. As described above, in the present embodiment, it is preferable that the difference between the temperature at which the oxide semiconductor layer is formed and the temperature at which OS annealing is performed on the oxide semiconductor layer 130 is 350° C. or higher. Forming the oxide semiconductor layer while cooling the substrate makes it possible to obtain an oxide semiconductor layer having few crystalline components immediately after the formation.

In addition, the oxygen partial pressure in a chamber during deposition is preferably 1% or more and 10% or less, preferably 1% or more and 5% or less, and more preferably 2% or more and 4% or less. When the oxygen partial pressure is high, the oxide semiconductor contains excessive oxygen, resulting in the formation of microcrystals in the oxide semiconductor layer. On the other hand, when the partial pressure of oxygen is less than 1%, the composition of oxygen in the oxide semiconductor layer becomes uneven, and there is a possibility that an oxide semiconductor layer containing a large amount of microcrystals or an oxide semiconductor layer which does not crystallize even when a heat treatment is performed is deposited.

Next, after the oxide semiconductor layer 130 is formed by patterning, a heat treatment (OS annealing) is performed on the oxide semiconductor layer 130 (step S1003 in FIG. 4). In the OS annealing, the oxide semiconductor layer 130 in an amorphous state is crystallized by performing a heat treatment on the oxide semiconductor layer 130 in an atmospheric atmosphere at a temperature of 250° C. or higher and 500° C. or lower (preferably 300° C. or higher and 500° C. or lower, and more preferably 350° C. or higher and 450° C. or lower). The heating atmosphere is not limited to an atmospheric atmosphere, but is preferably an oxidizing atmosphere (an atmosphere containing oxygen). In addition, the oxidizing atmosphere is preferably a wet atmosphere (specifically, a wet atmospheric atmosphere). Furthermore, the treatment time of the heat treatment is 15 minutes or more and 120 minutes or less, or 30 minutes or more and 60 minutes or less after reaching the predetermined temperature. In the present embodiment, the temperature of the OS annealing is set at 350° C.

In the present embodiment, the substrate in which the oxide semiconductor layer 130 is formed is charged into a heating furnace having a heating medium (for example, a support plate) maintained at a set temperature (250° C. or higher and 500° C. or lower, in the present embodiment, 350° C.) in advance. The support plate as a heating medium serves to support the substrate and to heat the substrate and the coating formed on the substrate (including the oxide semiconductor layer 130). The oxide semiconductor layer 130 is rapidly heated by placing the substrate on which the oxide semiconductor layer 130 is formed. When installing the substrate in the heating furnace, it is desirable to keep the temperature drop of the support plate within 15%, within 10%, or within 5% of the set temperature. That is, it is preferable to control the temperature of the support plate so that the oxide semiconductor layer 130 reaches the set temperature in as short a time as possible.

As described above, in the present embodiment, after the oxide semiconductor layer is patterned to form the oxide semiconductor layer 130, a crystallization process of the oxide semiconductor layer 130 is performed. This is because the etching resistance of the oxide semiconductor layer used in the present embodiment is greatly enhanced by crystallization. That is, in the present embodiment, the oxide semiconductor layer is patterned before OS annealing because the oxide semiconductor layer 130 after OS annealing exhibits extremely high etching resistance to the etchant (etching solution and etching gas). The etching resistance of the oxide semiconductor layer used in the present embodiment will be described later.

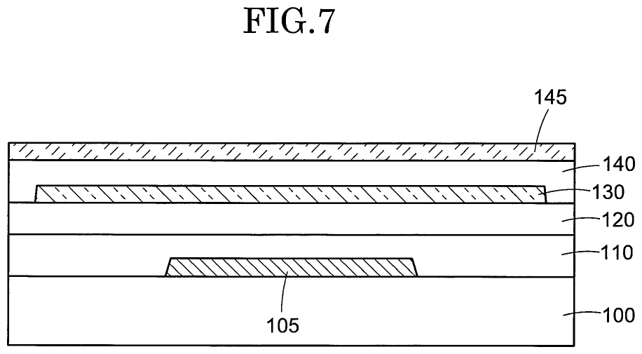

Next, as shown in FIG. 4 and FIG. 7, the gate insulating layer 140 and a metal oxide layer 145 are formed (step S1004 in FIG. 4). For example, a silicon oxide layer is formed as the gate insulating layer 140. The gate insulating layer 140 is formed by a CVD method. It is desirable to form the gate insulating layer 140 as an insulating layer having as few defects as possible. In the present embodiment, the deposition temperature of the gate insulating layer 140 is set at 350° C. For example, a thickness of the gate insulating layer 140 is 50 nm or more and 300 nm or less, 60 nm or more and 200 nm or less, or 70 nm or more and 150 nm or less. In the present embodiment, the thickness of the gate insulating layer 140 is 100 nm.

The metal oxide layer 145 is formed by a sputtering method. By using a sputtering method for the deposition of the metal oxide layer 145, oxygen is implanted into the gate insulating layer 140 when the metal oxide layer 145 is formed. Therefore, the gate insulating layer 140 after the metal oxide layer 145 is formed contains a large amount of oxygen. For example, a thickness of the metal oxide layer 145 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide layer 145. As described above, since the aluminum oxide has a high-barrier property against gases, it is possible to suppress the oxygen implanted into the gate insulating layer 140 from diffusing upward during the heat treatment described later.

In the case where the metal oxide layer 145 is formed by a sputtering method, a process gas used in sputtering remains in the film of the metal oxide layer 145. For example, in the case where Ar is used as the process gas for sputtering, Ar may remain in the film of the metal oxide layer 145. The remaining Ar can be detected by SIMS (Secondary Ion Mass Spectrometry) spectrometry or the like with respect to the metal oxide layer 145.

Next, in the state where the metal oxide layer 145 is formed on the gate insulating layer 140, a heat treatment (oxidation annealing) for supplying oxygen to the oxide semiconductor layer 130 is performed (step S1005 of FIG. 4). During the process from the formation of the oxide semiconductor layer 130 to the formation of the gate insulating layer 140 on the oxide semiconductor layer 130, oxygen deficiencies may occur on the top surface and the side surface of the oxide semiconductor layer 130. Oxygen released from the insulating layer 120 and the gate insulating layer 140 is supplied to the oxide semiconductor layer 130 by the oxidation annealing, and the oxygen deficiencies are repaired. The oxidation annealing may be performed at a temperature of 250° C. or higher and 500° C. or lower (preferably 300° C. or higher and 500° C. or lower, and more preferably 350° C. or higher and 450° C. or lower). In the present embodiment, the oxidation annealing is performed at a temperature of 350° C.

Oxygen released from the insulating layer 120 and the gate insulating layer 140 is supplied to the oxide semiconductor layer 130 by the oxidation annealing. Although hydrogen may be released from the insulating layer 110 by the oxidation annealing described above, most of the released hydrogen is captured by the oxygen contained in the insulating layer 120 before reaching the oxide semiconductor layer 130.

As described above, oxygen can be supplied to the oxide semiconductor layer 130 by the oxidation annealing. During the oxidation annealing, the upward diffusion of the oxygen implanted into the gate insulating layer 140 is blocked by the metal oxide layer 145, so that the oxygen is suppressed from being released into the atmosphere. Therefore, oxygen can be efficiently supplied to the oxide semiconductor layer 130 during the oxidation annealing.

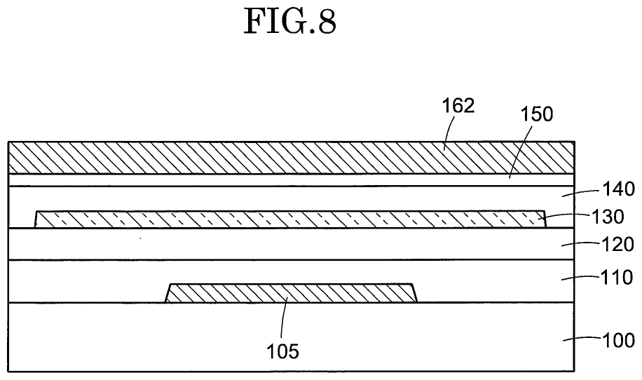

Next, as shown in FIG. 4 and FIG. 8, after the oxidation annealing, the metal oxide layer 145 is etched and removed (step S1006 in FIG. 4). The etching of the metal oxide layer 145 may be wet etching or dry etching. For example, dilute hydrofluoric acid (DHF) is used in the wet etching.

Next, the buffer layer 150 and a conductive layer 162 are formed on the gate insulating layer 140 (step S1007 of FIG. 4). The buffer layer 150 is formed by a CVD method or a sputtering method. In the present embodiment, a silicon oxide layer having a thickness of 50 nm is formed as the buffer layer 150. The conductive layer 162 is formed by a sputtering method. Although an alloy composed of molybdenum and tungsten is used as the conductive layer 162 in the present embodiment, the present invention is not limited to this. The conductive layer 162 is a conductive layer for forming the above-described gate wiring 160.

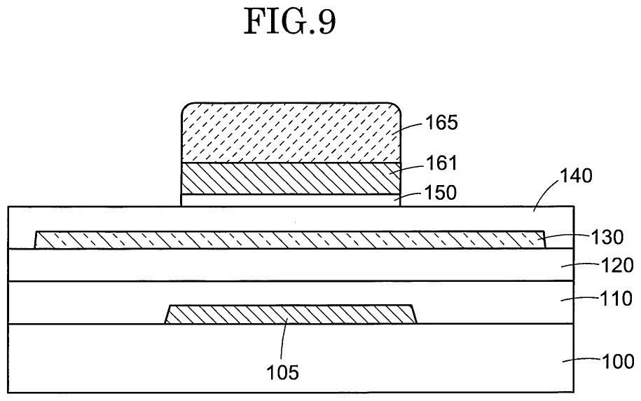

Next, as shown in FIG. 4 and FIG. 9, the buffer layer 150 and the conductive layer 162 are patterned (step S1008 in FIG. 4). Specifically, a resist mask 165 is formed on the conductive layer 162, and the buffer layer 150 and the conductive layer 162 are collectively etched using the resist mask 165 as a mask. The patterning process shown in step S1008 forms a patterned buffer layer 150 and conductive layer 161. The etching of the buffer layer 150 and the conductive layer 162 may be wet etching or dry etching.

In the present embodiment, since both the gate insulating layer 140 and the buffer layer 150 are made of silicon oxide, the gate insulating layer 140 is also etched when the buffer layer 150 is etched and patterned and then the etching is continued. Therefore, in the present embodiment, the gate insulating layer 140 is prevented from being excessively etched by controlling the etching time. If a material having a large selectivity with respect to the gate insulating layer 140 is used as the buffer layer 150, the above-described control of the etching time may not be performed.

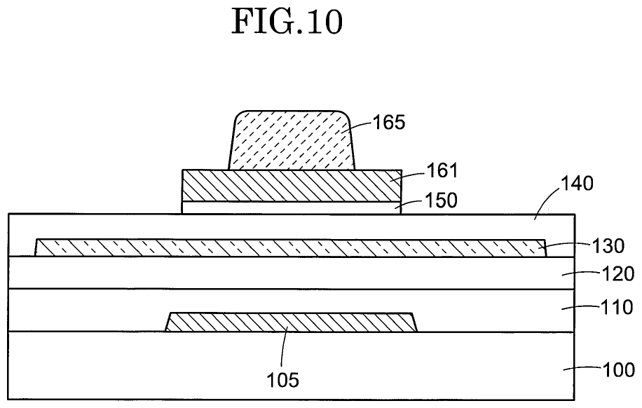

Next, as shown in FIG. 4 and FIG. 10, an ashing treatment is performed on the resist mask 165 (step S1009 in FIG. 4). The resist mask 165 is subjected to the ashing treatment (heat treatment under an oxygen atmosphere), thereby reducing the overall volume of the resist mask 165. Therefore, as shown in FIG. 10, when viewed in a cross section, the end portion of the resist mask 165 is retracted and part of the conductive layer 161 is exposed. As will be described later, the retraction rate of the resist mask 165 corresponds to the length (ΔL) of the LDD region 130b shown in FIG. 1.

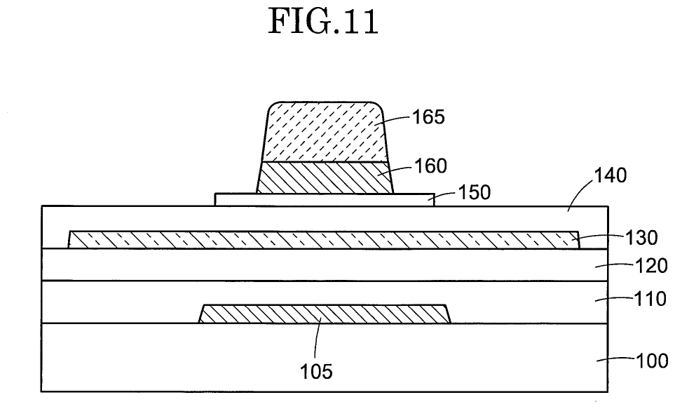

Next, as shown in FIG. 4 and FIG. 11, an etching process is performed on the conductive layer 161 using the resist mask 165 as a mask to form the gate wiring 160 (step S1010 in FIG. 4). The etching of the conductive layer 161 may be wet etching or dry etching. As shown in FIG. 11, the gate wiring 160 is formed to expose part of the buffer layer 150. The exposed region corresponds to the non-overlapping region 150b shown in FIG. 3.

When the conductive layer 161 is etched, the selectivity between the buffer layer 150 and the conductive layer 161 is preferably as high as possible. In the present embodiment, since the buffer layer 150 is thin, if the selectivity between the buffer layer 150 and the conductive layer 161 is small, the buffer layer 150 may disappear due to over-etching after the gate wiring 160 is formed. Therefore, it is desirable that a large selectivity be ensured by combining the conductive layer 161 and the buffer layer 150.

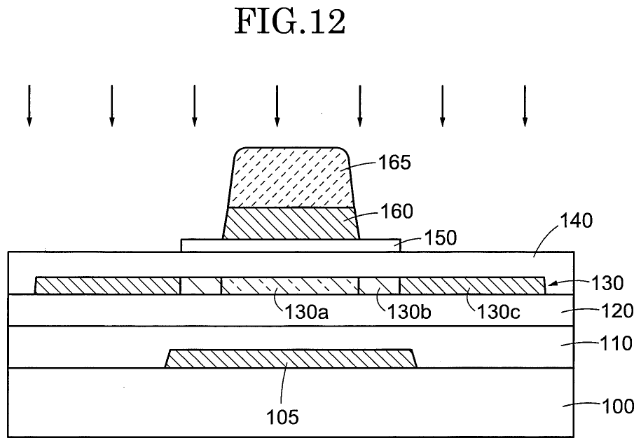

Next, as shown in FIG. 4 and FIG. 12, ions are implanted from above the gate wiring 160 and the buffer layer 150, and an impurity is added to the oxide semiconductor layer 130 (step S1011 in FIG. 4). Phosphorus, boron, argon, or the like can be used as the impurity. Since the purpose of adding the impurity is to make an oxygen deficiency with respect to a region of part of the oxide semiconductor layer 130 to enhance the conductivity, it is preferable to use an element having a large atomic radius as the impurity.

Although an example in which an impurity is added by ion-implantation is shown, ion doping may be used. In the present embodiment, boron is added using ion implantation. Although conditions of ion-implantation of the present embodiment are 30 keV for the acceleration voltage and 1×10¹⁵/cm² for the dose, the present invention is not limited to this example. In addition, although an example in which ion implantation is performed while the resist mask 165 remains is shown in the present embodiment, ion implantation may be performed after the resist mask 165 is removed, using the gate wiring 160 as a mask.

As shown in FIG. 12, when the ion implantation of impurities is performed on the oxide semiconductor layer 130, the LDD region 130b and the conductive region 130c are formed in the oxide semiconductor layer 130. In this case, a region that is maintained in the original condition without implanting the impurities functions as the channel region 130a. An impurity is added to the conductive region 130c via the gate insulating layer 140. On the other hand, an impurity is added to the LDD region 130b via the buffer layer 150 and the gate insulating layer 140. Therefore, the concentration of the impurity added to the LDD region 130b is relatively lower than the concentration of the impurity added to the conductive region 130c. For example, if the thickness of the buffer layer 150 is appropriately controlled, the concentration of the impurity to be added to the LDD region 130b can be one order of magnitude lower than the concentration of the impurity to be added to the conductive region 130c. As a result, the conductivity of the LDD region 130b is less than the conductivity of the conductive region 130c. In other words, the electrical resistivity of the LDD region 130b is higher than the electrical resistivity of the conductive region 130c. In other words, the sheet resistance of the LDD region 130b is greater than the sheet resistance of the conductive region 130c.

As described above, the conductive region 130c formed by the step S1011 shown in FIG. 12 functions as a source region and a drain region of the semiconductor device 10. When the resistance of the oxide semiconductor layer 130 of the present embodiment is reduced by the introduction of oxygen deficiencies, the resistance value becomes significantly lower than the conventional oxide semiconductor layer. Specifically, the resistance (sheet resistance) of the conductive region 130c in the oxide semiconductor layer 130 of the present embodiment is 1000 Ω/sq. or less (preferably 500 Ω/sq. or less, more preferably 250 Ω/sq. or less).

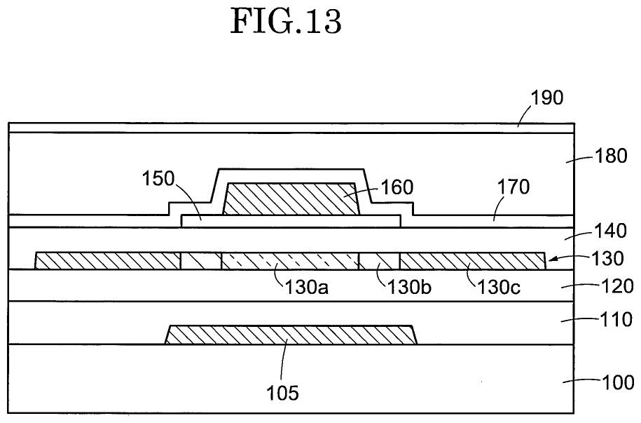

Next, as shown in FIG. 4 and FIG. 13, the insulating layers 170 to 190 are formed as passivation layers on the gate insulating layer 140, the buffer layer 150, and the gate wiring 160 (step S1012 of FIG. 4). The insulating layers 170 to 190 are formed by a CVD method. In the present embodiment, a silicon oxide layer, a silicon nitride layer, and a silicon oxide layer are formed as the insulating layers 170 to 190, respectively. The deposition temperature of the insulating layers 170 to 190 is preferably set to 250° C. or higher and 500° C. or lower (preferably 300° C. or higher and 450° C. or lower, and more preferably 325° C. or higher and 400° C. or lower). In the present embodiment, the deposition temperature of the insulating layers 170 to 190 is set to 350° C. Thicknesses of the insulating layers 170 to 190 may be 30 nm or more and 500 nm or less. In the present embodiment, the thicknesses of the insulating layers 170 to 190 are 100 nm, 300 nm, and 30 nm, respectively. However, the configuration of the passivation layer is not limited to the above-described example. For example, the passivation layer may have a single-layer structure or a two-layer structure, or may have a stacked structure of four or more layers. In addition, the insulating layer used as the passivation layers may be any insulating layer selected from silicon oxide (SiOₓ), silicon nitride (SiNₓ), silicon oxynitride (SiOₓN_{y}), or silicon nitride oxide (SiOₓN_{y}).

The insulating layers 170 to 190 function as passivation layers (protective layers) to prevent the intrusion of gas and moisture from the outside. As described above, the insulating layers 170 to 190 also have a function to insulate the gate wiring 160 and the source/drain wiring 200. Furthermore, in the present embodiment, since a silicon nitride layer is used as the insulating layer 180, it is possible to promote a reduction in resistance of the conductive region 130c of the oxide semiconductor layer 130.

Since ammonia is used as the source gas when the silicon nitride layers are formed by a CVD method, the insulating layer 180 contains a large amount of hydrogen. Therefore, when the insulating layer 180 is formed and after the insulating layer 180 is formed, the insulating layer 180 is heated to diffuse hydrogen from the insulating layer 180. The diffused hydrogen reaches the oxide semiconductor layer 130 via the gate insulating layer 140 and the insulating layer 170. In this case, hydrogen is trapped in the oxygen deficiency in the conductive region 130c formed by the ion implantation described above, thereby forming a donor level. This promotes a reduction in resistance of the conductive region 130c.

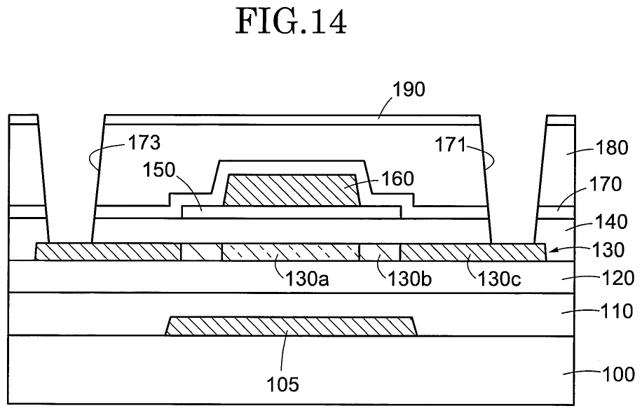

Next, as shown in FIG. 4 and FIG. 14, the contact holes 171 and 173 are formed in the gate insulating layer 140 and the insulating layers 170 to 190 (step S1013 in FIG. 4). The contact holes 171 and 173 expose a part of the conductive region 130c.

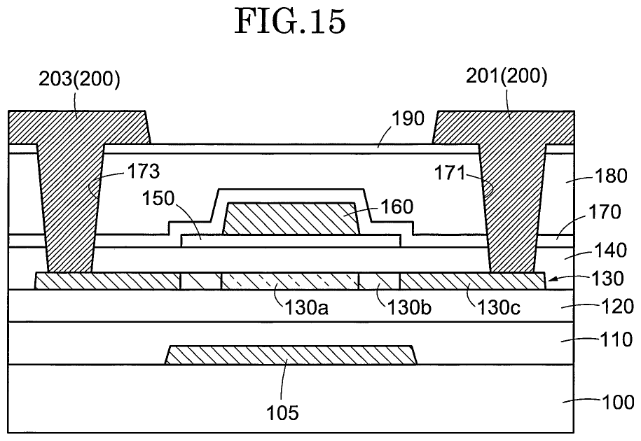

Finally, as shown in FIG. 4 and FIG. 15, the source/drain wiring 200 is formed on the conductive region 130c exposed by the contact holes 171 and 173 and on the insulating layer 180 (step S1014 of FIG. 4). The semiconductor device 10 shown in FIG. 1 is completed by the above-described process.

In the semiconductor device 10 manufactured by the manufacturing method of the present embodiment, electrical characteristics having a field-effect mobility of 20 cm²/Vs or more, 25 cm²/Vs or more, or 30 cm²/Vs or more can be obtained in a range where the channel length L of the channel region 130a is 1 μm or more and 4 μm or less and the channel width of the channel region 130a is 2 μm or more and 25 μm or less. The “field-effect mobility” in the present embodiment is the field-effect mobility in a saturated region of the semiconductor device 10 and means the maximum value of the field-effect mobility in a region where the potential difference (Vd) between the source wiring 201 and the drain wiring 203 is greater than the value (Vg−Vth) obtained by subtracting the threshold voltage (Vth) of the semiconductor device 10 from the voltage (Vg) supplied to the gate wiring 160.

### [Etching Resistance of Oxide Semiconductor Layer]

As described above, the oxide semiconductor layer used in the semiconductor device 10 of the present embodiment has excellent etching resistance. Specifically, the oxide semiconductor layer of the present embodiment is hardly etched by etchants (etching solutions) for wet etching, and the etching rates are very low.

Specifically, in a temperature range of 35° C. or higher and 45° C. or lower (for example, a range including an error of ±5° C. at a set temperature of 40° C.), the etching rate when the oxide semiconductor layer of the present embodiment is etched using an etching solution containing phosphoric acid as a main component (for example, a mixed acid etching solution or the like) is less than 3 nm/min, less than 2 nm/min, or less than 1 nm/min. The proportion of phosphoric acid in the etching solution is 50% or more, 60% or more, or 70% or more. The etching solution may contain nitric acid and acetic acid in addition to phosphoric acid. In contrast, in the oxide semiconductor layer (oxide semiconductor layer before OS annealing) having the amorphous structure of the present embodiment, the etching rate when it is etched using the etching solution in the temperature range of 35° C. or higher and 45° C. or lower is 100 nm/min or more.

In addition, the etching rate when the oxide semiconductor layer of the present embodiment is etched using an etching solution containing hydrogen fluoride (for example, a hydrofluoric acid solution) at room temperature (in this case, “25° C.±5° C.”) is less than 5 nm/min, less than 4 nm/min, or less than 3 nm/min. The proportion of hydrogen fluoride in the etching solution is 0.5%. On the other hand, in the oxide semiconductor layer having the amorphous structure of the present embodiment, the etching rate when the etching is performed using the above-described etching solution at room temperature is 15 nm/min or more.

Here, the etching rates of the various oxide semiconductor layers are shown in Table 1. Table 1 shows the etching rates for the mixed acid etching solution and the 0.5% hydrofluoric acid solution in each sample prepared. “Mixed acid AT-2F (product name)” manufactured by Rasa Industries, Ltd. was used as the mixed acid etching solution. The proportion of phosphoric acid in the mixed acid etching solution is about 65%. In addition, the temperature of the mixed acid etching solution when etching each sample was set to 40° C., and the temperature of the 0.5% hydrofluoric acid solution was set to 22° C. In Table 1, Sample 1 is an oxide semiconductor layer having the polycrystalline structure of the present embodiment, Sample 2 is an oxide semiconductor layer having the amorphous structure of the present embodiment, and Sample 3 is an oxide semiconductor layer containing indium gallium zinc oxide (IGZO) having a ratio of indium of less than 50%.

TABLE 1

| | Mixed acid | 0.5% hydrofluoric |
|---|---|---|
| | etching solution | acid solution |
| Sample 1 | <0.1 nm/min | <2 nm/min |
| Sample 2 | 111 nm/min | >18 nm/min |
| Sample 3 | 162 nm/min | — |

As shown in Table 1, Sample 1 was hardly etched even when a mixed acid etching solution was used, and was etched at most at about 2 nm/min even when a 0.5% hydrofluoric acid solution was used. The etching rate of Sample 1 was 1/100 or less in the mixed acid etching solution and about 1/10 or less in the 0.5% hydrofluoric acid solution compared with the etching rate of Sample 2. In addition, the etching rate of Sample 1 was 1/100 or less in the mixed acid etching solution compared with the etching rate of Sample 3. As described above, Sample 1 was found to have significantly better etching resistance than Sample 2 and Sample 3.

The excellent etching resistance of the oxide semiconductor layer of the present embodiment is not obtained with a conventional polycrystalline oxide semiconductor layer manufactured at 500° C. or lower. Although the detailed mechanism is unknown, it can be said that such excellent etching resistance is evidence that the oxide semiconductor layer of the present embodiment has a polycrystalline structure different from the conventional one.

### Modification of First Embodiment

In the above-described method for manufacturing the semiconductor device 10, an example in which the volume change of the resist mask 165 is used in forming the gate wiring 160 has been described, but the present invention is not limited to this example, and the resist mask may be formed in two steps. Hereinafter, a modification of the first embodiment will be described.

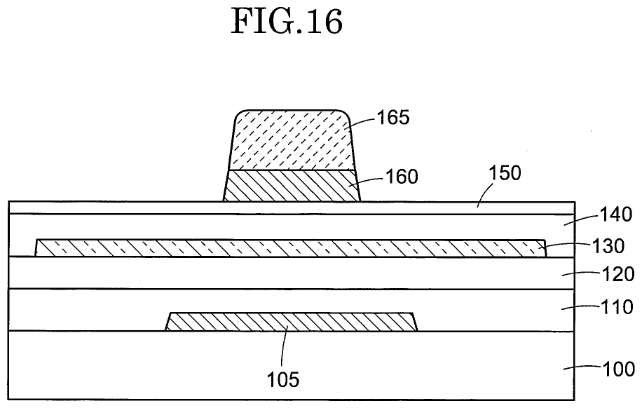

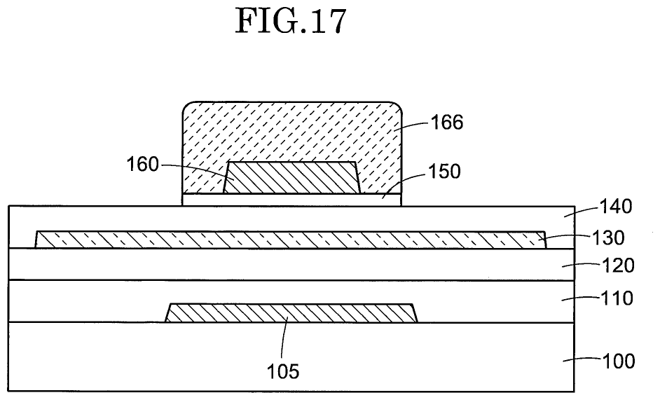

FIG. 16 and FIG. 17 are schematic cross-sectional views showing a method for manufacturing the semiconductor device 10 according to a modification of an embodiment of the present invention. The method for manufacturing the semiconductor device 10 of the present modification is the same for the processes shown in FIG. 5 to FIG. 8 and FIG. 12 to FIG. 15 described above. That is, the manufacturing method of the present modification corresponds to the manufacturing method described in the first embodiment in which the processes shown in FIG. 9 to FIG. 11 are different.

After the conductive layer 162 is formed by the processes of FIG. 5 to FIG. 8 (steps S1001 to S1007 of FIG. 4) described above, the conductive layer 162 is patterned as shown in FIG. 16. Specifically, the resist mask 165 is formed on the conductive layer 162, and the conductive layer 162 is etched to form the gate wiring 160. As described above, by increasing the selectivity between the buffer layer 150 and the gate wiring 160, the buffer layer 150 can be used as an etching stopper when the gate wiring 160 is formed.

Next, as shown in FIG. 17, after the resist mask 165 is removed to form a new resist mask 166, the buffer layer 150 is patterned. Specifically, the resist mask 166 is formed on the buffer layer 150 and the gate wiring 160, and the buffer layer 150 is etched to form a pattern formed by the buffer layer 150.

In this case, as shown in FIG. 17, in a cross-sectional view along the first direction (see FIG. 1), a width of the resist mask 166 is larger than the width of the gate wiring 160. Therefore, a region that does not overlap the gate wiring 160, that is, the non-overlapping region 150b shown in FIG. 3 is formed in the pattern formed by the buffer layer 150. Therefore, a distance from the side surface of the gate wiring 160 to the side surface of the resist mask 166 determines the length of the LDD region 130b.

When the process shown in FIG. 17 is completed, the semiconductor device 10 of the first embodiment is completed through the same process as that of FIG. 12 to FIG. 15 described above.

As described above, in the method for manufacturing the semiconductor device 10 according to the first embodiment, the patterning process of the buffer layer 150 and the gate wiring 160 may be separately performed. In this case, since the length of the LDD region 130b (that is, the length of the buffer layer 150 in the non-overlapping region 150b) can be controlled by the resolution of the photolithography, it is preferable when the semiconductor device 10 is miniaturized.

### Second Embodiment

In the present embodiment, an example in which the configuration of the gate insulating layer 140 is different from that of the first embodiment will be described. Specifically, in a semiconductor device 10a of the present embodiment, part of the gate insulating layer 140 is removed, and the conductive region 130c of the oxide semiconductor layer 130 is not covered with the gate insulating layer 140. In the description of the present embodiment, parts common to those of the first embodiment are shown in the drawings using the same reference signs, and the description will focus on parts different from those of the first embodiment.

### [Configuration of Semiconductor Device]

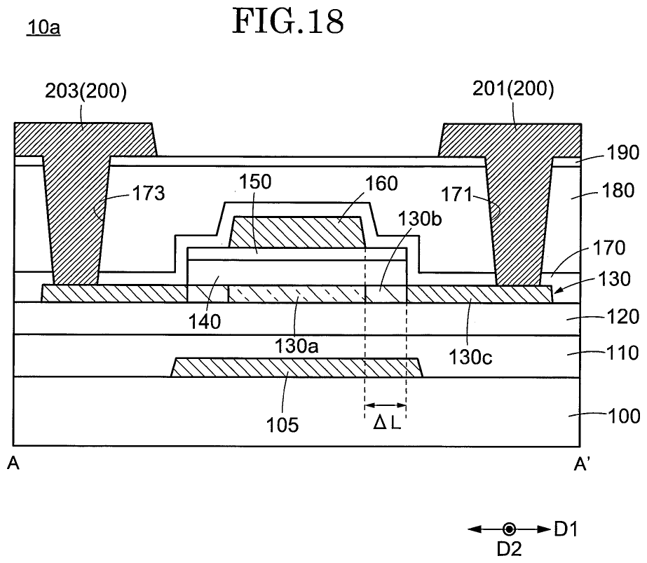

A configuration of a semiconductor device 10a according to an embodiment of the present invention will be described. FIG. 18 is a schematic cross-sectional view showing a configuration of the semiconductor device 10a according to an embodiment of the present invention. A difference from the semiconductor device 10 shown in FIG. 1 is that part of the gate insulating layer 140, specifically, part of the gate insulating layer 140 that does not overlap the buffer layer 150 is removed. Therefore, the conductive region 130c is exposed from the gate insulating layer 140. In other words, the conductive region 130c does not overlap the gate insulating layer 140 and is in contact with the insulating layer 170. The insulating layer 170 is in contact with the conductive region 130c as well as the side surface of the gate insulating layer 140 and the insulating layer 120.

Since the gate insulating layer 140 is present only vertically below the buffer layer 150, the side surface of the gate insulating layer 140 coincides with the side surface of the buffer layer 150 in the first direction. However, the phrase “the side surfaces coincide with each other” includes not only the case where the side surfaces are completely coincident with each other, but also the case where the side surfaces do not coincide with each other within a range in which the side surfaces are regarded as substantially coincident with each other (for example, within a range in which the deviation amounts of the side surfaces from each other are 3 nm or more and 15 nm or less). As shown in FIG. 18, the difference between the side surface of the gate wiring 160 and the side surface of the buffer layer 150 in the first direction (that is, the difference between the side surface of the gate wiring 160 and the side surface of the gate insulating layer 140) corresponds to the length (ΔL) of the LDD region 130b.

### [Method for Manufacturing Semiconductor Device]

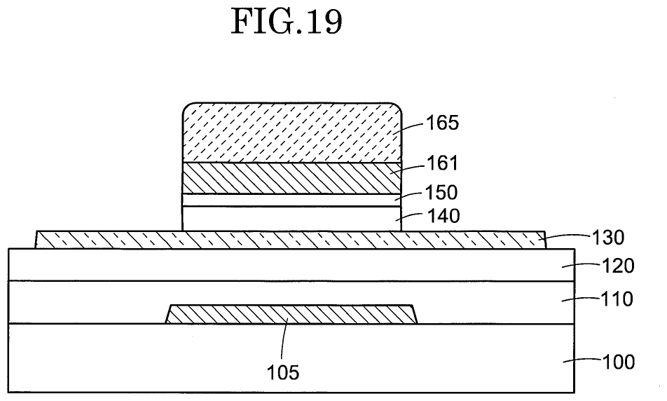

Next, a method for manufacturing the semiconductor device 10a according to an embodiment of the present invention will be described. FIG. 19 to FIG. 22 are schematic cross-sectional views showing the method for manufacturing the semiconductor device 10a according to an embodiment of the present invention.

The method for manufacturing the semiconductor device 10a of the present embodiment is the same as the processes shown in FIG. 5 to FIG. 8, and FIG. 14 and FIG. 15 of the first embodiment (although the device structure to be processed is different in the processes shown in FIG. 14 and FIG. 15). That is, the manufacturing method of the present embodiment corresponds to the manufacturing method described in the first embodiment in which the processes shown in FIG. 9 to FIG. 13 are different.

After the conductive layer 162 is formed by the process of FIG. 5 to FIG. 8 (steps S1001 to S1007 of FIG. 4) of the first embodiment, the conductive layer 162, the buffer layer 150, and the gate insulating layer 140 are patterned as shown in FIG. 19. Specifically, the resist mask 165 is formed on the conductive layer 162 and etched from the conductive layer 162 to the gate insulating layer 140 at once to expose part of the oxide semiconductor layer 130. As discussed above, since the etching resistance of the oxide semiconductor layer 130 is so high, the selectivity to the gate insulating layer 140 is high. However, in the present embodiment, since both the gate insulating layer 140 and the insulating layer 120 are formed of silicon oxide layers, it is preferable to perform temporal control so as not to excessively etch the insulating layer 120.

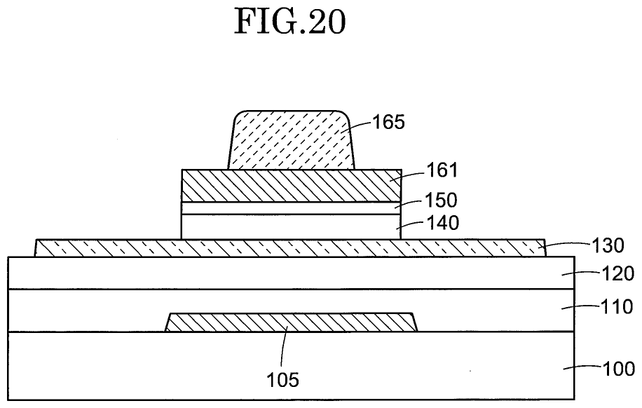

Next, as shown in FIG. 20, an ashing treatment is performed on the resist mask 165. The process shown in FIG. corresponds to the step S1009 of FIG. 4 of the first embodiment. By performing an ashing treatment on the resist mask 165, the overall volume of the resist mask 165 is reduced. The amount of retraction of the resist mask 165 corresponds to the length (ΔL) of the LDD region 130b shown in FIG. 1.

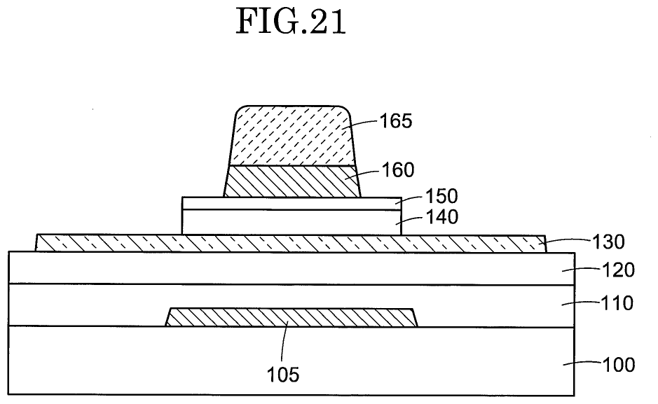

Next, as shown in FIG. 21, an etching process is performed on the conductive layer 161 using the resist mask 165 as a mask to form the gate wiring 160. The process shown in FIG. 21 corresponds to the step S1010 of FIG. 4 of the first embodiment. The gate wiring 160 is formed to expose part of the buffer layer 150. The exposed region corresponds to the non-overlapping region 150b shown in FIG. 3.

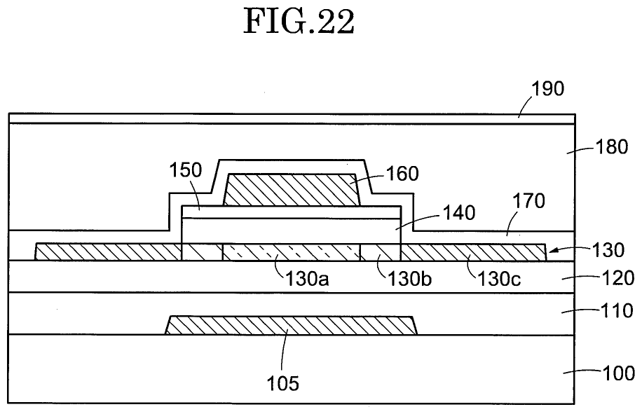

Next, as shown in FIG. 22, the insulating layers 170 to 190 are formed as passivation layers on the oxide semiconductor layer 130, the gate insulating layer 140, the buffer layer 150, and the gate wiring 160. The process shown in FIG. 22 corresponds to the step S1012 of FIG. 4 of the first embodiment. In the present embodiment, similar to the first embodiment, a silicon oxide layer, a silicon nitride layer, and a silicon oxide layer are formed as the insulating layers 170 to 190, respectively.

In this case, unlike the first embodiment, a process of adding impurities to the oxide semiconductor layer 130 (a process corresponding to the step S1011 in FIG. 4 of the first embodiment) before forming the insulating layers 170 to 190 is not performed in the present embodiment. Alternatively, in the present embodiment, the resistance of part of the oxide semiconductor layer 130 may be reduced by the process of forming the insulating layers 170 to 190.

As shown in FIG. 22, when the insulating layers 170 to 190 are formed, the LDD region 130b and the conductive region 130c are formed in the oxide semiconductor layer 130. As described in the first embodiment, since the insulating layer 180 contains a large amount of hydrogen, hydrogen diffuses from the insulating layer 180 when the insulating layer 180 is heated during deposition. In this case, in the present embodiment, the oxide semiconductor layer 130 and the insulating layer 170 are in contact with each other because the gate insulating layer 140 is not present on part of the oxide semiconductor layer 130 (part to be the conductive region 130c). That is, hydrogen diffused from the insulating layer 180 easily reaches the oxide semiconductor layer 130 via the insulating layer 170. Therefore, the conductive region 130c is formed in a region of the oxide semiconductor layer 130 in contact with the insulating layer 170.

Hydrogen diffuses into a region of the oxide semiconductor layer 130 that does not overlap the gate wiring 160 and overlaps the gate insulating layer 140 and the buffer layer 150 (that is, a region that overlaps the non-conductive overlapping region 150b shown in FIG. 3) at a relatively lower level than the conductive region 130c. Therefore, the LDD region 130b having a resistance greater than that of the conductive region 130c is formed in a region of the oxide semiconductor layer 130 that does not overlap the gate wiring 160 but overlaps the gate insulating layer 140 and the buffer layer 150. In addition, since hydrogen hardly diffuses into a region of the oxide semiconductor layer 130 positioned vertically below the gate wiring 160, the original condition is maintained and functions as a channel region.

Furthermore, in the semiconductor device 10a of the present embodiment, similar to the semiconductor device 10 of the first embodiment, the conductivity of the LDD region 130b is smaller than the conductivity of the conductive region 130c. In other words, the resistance (for example, sheet resistance) of the LDD region 130b is greater than the resistance of the conductive region 130c. Specifically, the resistance (sheet resistance) of the conductive region 130c in the oxide semiconductor layer 130 of the present embodiment is 1000 Ω/sq. or less (preferably 500 Ω/sq. or less, more preferably 250 Ω/sq. or less).

When the process shown in FIG. 22 is completed, the semiconductor device 10a of the second embodiment is completed through a similar process as in FIG. 14 and FIG. 15 of the first embodiment.

In the method for manufacturing the semiconductor device 10a of the second embodiment, in the process shown in FIG. 19, the process of contiguously etching the gate insulating layer 140 from the etching of the buffer layer 150 is simply added, and the impurity-adding process shown in FIG. 12 of the first embodiment can be omitted. Therefore, according to the present embodiment, the manufacturing process of the semiconductor device can be simplified as compared with the first embodiment.

### Modification of Second Embodiment

In the method for manufacturing the semiconductor device 10a described above, although an example in which the volume change of the resist mask 165 is used when forming the gate wiring 160 has been described, the present invention is not limited to this example, and the resist mask may be formed in two steps. Hereinafter, a modification of the second embodiment will be described.

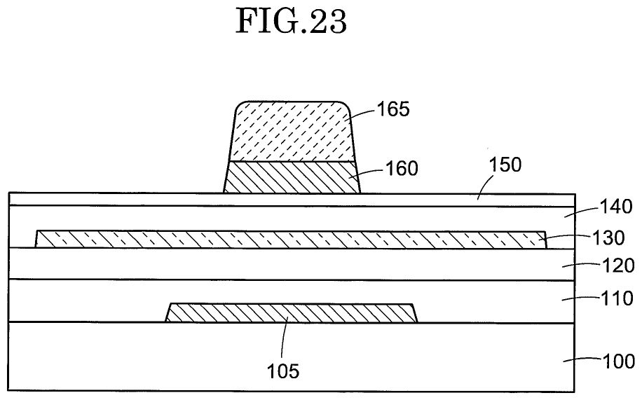

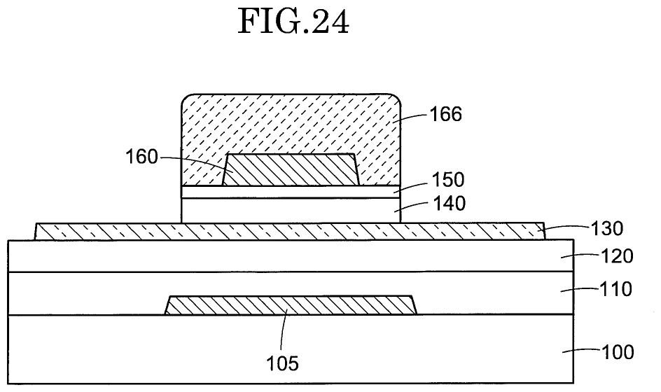

FIG. 23 and FIG. 24 are schematic cross-sectional views showing a method for manufacturing the semiconductor device 10a according to a modification of an embodiment of the present invention. The method for manufacturing the semiconductor device 10a of the present modification corresponds to the manufacturing method described in the second embodiment in which the processes shown in FIG. 19 to FIG. 21 are different.

First, after the conductive layer 162 is formed by the process of FIG. 5 to FIG. 8 (steps S1001 to S1007 of FIG. 4) of the first embodiment, the conductive layer 162 is patterned as shown in FIG. 23. Specifically, the resist mask 165 is formed on the conductive layer 162, and the conductive layer 162 is etched to form the gate wiring 160. As described above, by increasing the selectivity between the buffer layer 150 and the gate wiring 160, the buffer layer 150 can be used as an etching stopper when the gate wiring 160 is formed.

Next, as shown in FIG. 24, after the resist mask 165 is removed to form the new resist mask 166, the buffer layer 150 and the gate insulating layer 140 are patterned. Specifically, the resist mask 166 is formed on the buffer layer 150 and the gate wiring 160, and the buffer layer 150 and the gate insulating layer 140 are etched to form a pattern formed by the buffer layer 150 and the gate insulating layer 140. The process shown in FIG. 24 exposes part of the oxide semiconductor layer 130 (a region that will later become the conductive region 130c).

As shown in FIG. 24, in a cross-sectional view along the first direction (see FIG. 1), the width of the resist mask 166 is larger than the width of the gate wiring 160. Therefore, a region that does not overlap the gate wiring 160, that is, the non-overlapping region 150b shown in FIG. 3 is formed in the pattern formed by the buffer layer 150. Therefore, a distance from the side surface of the gate wiring 160 to the side surface of the resist mask 166 determines the length of the LDD region 130b.

Once the process shown in FIG. 24 is complete, the resist mask 166 is removed, and then the insulating layers 170 to 190 are formed to form the channel region 130a, the LDD region 130b and the conductive region 130c in the oxide semiconductor layer 130, similar to the process shown in FIG. 22. Then, the semiconductor device 10a of the second embodiment is completed through the same processes as those in FIG. 14 and FIG. 15 of the first embodiment.

As described above, in the method for manufacturing the semiconductor device 10a of the second embodiment, the patterning process of the buffer layer 150 and the gate wiring 160 can be performed separately for different processes. In this case, since the length of the LDD region 130b (that is, the length of the buffer layer 150 in the non-overlapping region 150b) can be controlled by the resolution of the photolithography, it is preferable when the semiconductor device 10a is miniaturized.

### Third Embodiment

Although an example in which the oxide semiconductor layer 130 is arranged so as to be in contact with the insulating layer 120 is shown in the first embodiment and the second embodiment, a metal oxide layer may be arranged between the insulating layer 120 and the oxide semiconductor layer 130. In the description of the present embodiment, parts common to those of the first embodiment are shown in the drawings using the same reference signs, and the description will focus on parts different from those of the first embodiment.

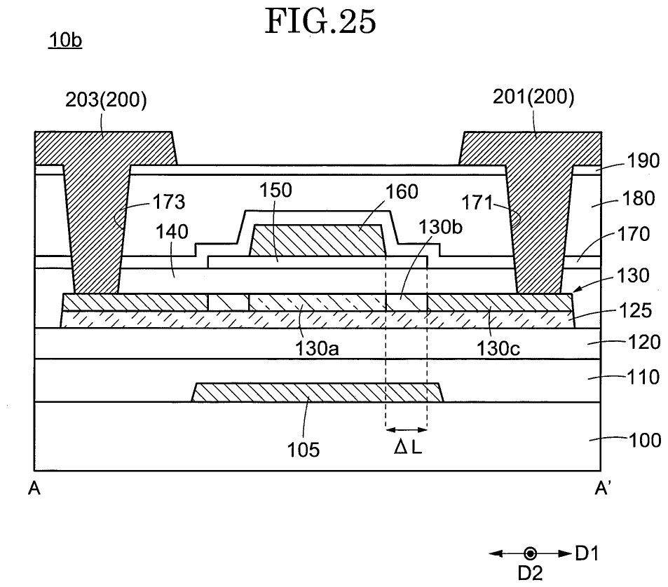

FIG. 25 is a schematic cross-sectional view showing a configuration of a semiconductor device 10b according to an embodiment of the present invention. The basic configuration is the same as the semiconductor device 10 shown in FIG. 1, but in the semiconductor device 10b of the present embodiment, a metal oxide layer 125 is arranged between the insulating layer 120 and the oxide semiconductor layer 130. In the present embodiment, a metal oxide containing aluminum as a main component (specifically, an aluminum oxide (AlOₓ) layer) is used as the metal oxide layer 125. For example, the metal oxide layer 125 can be formed by a sputtering method.

As shown in FIG. 25, in the present embodiment, the metal oxide layer 125 has the same pattern shape as the oxide semiconductor layer 130. In the present embodiment, after the metal oxide layer 125 and the oxide semiconductor layer 130 are contiguously stacked, processes of steps S1002 and S1003 of FIG. 4 are performed to obtain a polycrystalline oxide semiconductor layer 130. Thereafter, the metal oxide layer 125 may be etched using the oxide semiconductor layer 130 as a mask to form the metal oxide layer 125 having the same pattern shape as the oxide semiconductor layer 130.

For example, a thickness of the metal oxide layer 125 is 1 nm or more and 10 nm or less, 1 nm or more and 4 nm or less, or 1 nm or more and 3 nm or less. In the present embodiment, the thickness of the metal oxide layer 125 is 3 nm. In the present embodiment, the aluminum oxide layer used as the metal oxide layer 125 has a high-barrier property against gases even when the thickness is 1 nm or more and 10 nm or less. Therefore, the metal oxide layer 125 of the present embodiment blocks hydrogen and oxygen released from the insulating layer 120, and suppresses the hydrogen and oxygen released from below from reaching the oxide semiconductor layer 130.

Since the oxide semiconductor layer 130 of the present embodiment has an indium ratio of 50% or more as described above, a semiconductor device with high mobility can be realized, but oxygen is easily reduced, and oxygen deficiencies are easily formed in the layer. Therefore, it is preferable that the metal oxide layer 125 blocks hydrogen released from the insulating layer 120 to suppress the reduction reaction of the oxide semiconductor layer 130.

In addition, after the oxide semiconductor layer 130 is formed, more oxygen deficiencies are formed on the upper layer side of the oxide semiconductor layer 130 than on the lower layer side in various manufacturing processes (such as a patterning process). That is, the oxygen deficiencies in the oxide semiconductor layer 130 are distributed non-uniformly in the thickness direction. In this case, if enough oxygen is supplied to repair the oxygen deficiencies formed on the upper layer side of the semiconductor layer 130, excessive oxygen is supplied to the lower layer side of the oxide semiconductor layer 130. As a result, the excessively supplied oxygen forms a defect level different from the oxygen deficiencies, which may lead to phenomenon such as characteristic fluctuations or reduction in field-effect mobility during a reliability test. Therefore, it can be said that blocking oxygen released from the insulating layer 120 by the metal oxide layer 125 is also preferable to suppress an excessive oxygen supply to the lower layer of the oxide semiconductor layer 130.

As described above, in the present embodiment, when the oxidation annealing shown in the step S1005 of FIG. 1 is performed, it is possible to supply oxygen to the top surface and the side surface of the oxide semiconductor layer 130 having a relatively large amount of oxygen deficiencies while suppressing the supply of oxygen to the lower surface of the oxide semiconductor layer 130 having a small amount of oxygen deficiencies. Therefore, during the oxidation annealing, oxygen can be efficiently supplied to the oxide semiconductor layer 130, and the reliability of the semiconductor device 10 can be improved.

In addition, although an example of applying an embodiment to the semiconductor device 10 shown in FIG. 1 of the first embodiment has been described, the embodiment can also be applied to the semiconductor device 10a shown in FIG. 18 of the second embodiment.

### Fourth Embodiment

In the fourth embodiment, a display device 20 using the semiconductor device according to an embodiment of the present invention will be described. In the embodiment described below, the semiconductor device 10 described in the first embodiment is used as an element constituting a circuit of a liquid crystal display device. However, the present invention is not limited to this example, and the semiconductor device described in the second embodiment or third embodiment may be used as the element constituting the circuit of the liquid crystal display device.

### [Outline of Display Device]

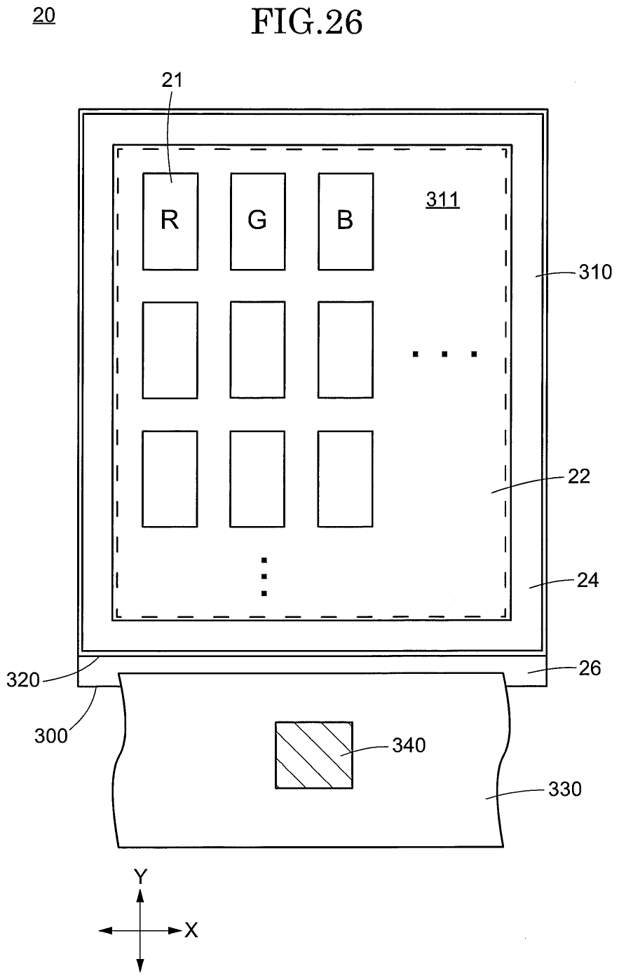

FIG. 26 is a schematic plan view showing an entire configuration of the display device 20 according to an embodiment of the present invention. As shown in FIG. 26, the display device 20 includes an array substrate 300, a seal part 310, a counter substrate 320, a flexible printed circuit (FPC) substrate 330, and an IC chip 340. The array substrate 300 and the counter substrate 320 are bonded together by the seal part 310. A plurality of pixels 21 is arranged in a matrix in a liquid crystal region 22 surrounded by the seal part 310. The liquid crystal region 22 is a region that overlaps a liquid crystal element 311 described later in a plan view. In addition, with respect to the pixel 21, the letters “R,” “G,” and “B” indicate that they correspond to pixels for displaying red, green, and blue, respectively.

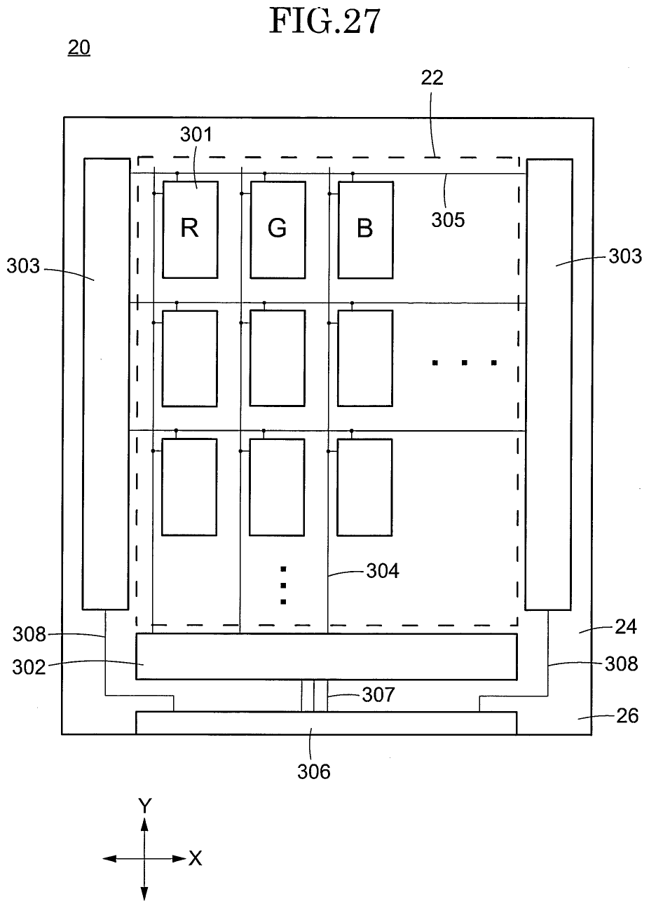

A seal region 24 where the seal part 310 is arranged is a region around the liquid crystal region 22. The flexible printed circuit substrate 330 is arranged in a terminal region 26. The terminal region 26 is a region of the array substrate 300 exposed from the counter substrate 320 and is arranged outside the seal region 24. The outside of the seal region 24 means the outside of a region where the seal part 310 is arranged and a region surrounded by the seal part 310. The IC chip 340 is arranged on the flexible printed circuit substrate 330. The IC chip 340 supplies a signal for driving each pixel circuit 301 (see FIG. 27) arranged in each pixel 21.

### [Circuit Configuration of Display Device]

FIG. 27 is a diagram showing a circuit configuration of the display device 20 according to an embodiment of the present invention. As shown in FIG. 27, a plurality of pixel circuits 301 is arranged in a matrix corresponding to each pixel 21 shown in FIG. 26. A source driver circuit 302 is arranged at a position adjacent to the liquid crystal region 22 on which the pixel circuit 301 is arranged in a direction Y (column direction). In addition, a gate driver circuit 303 is arranged at a position adjacent to the liquid crystal region 22 in a direction X (row direction). The source driver circuit 302 and the gate driver circuit 303 are arranged in the seal region 24. However, a region where the source driver circuit 302 and the gate driver circuit 303 are arranged is not limited to the seal region 24, and any region may be used as long as it is outside the region where the pixel circuit 301 is arranged.

A data signal line 304 extends from the source driver circuit 302 in the direction Y and is connected to the plurality of pixel circuits 301 arranged in the direction Y. A scanning signal line 305 extends from the gate driver circuit 303 in the direction X and is connected to the plurality of pixel circuits 301 arranged in the direction X.

A terminal part 306 is arranged in the terminal region 26. The terminal part 306 and the source driver circuit 302 are connected by a connecting wiring 307. Similarly, the terminal part 306 and the gate driver circuit 303 are connected by a connecting wiring 308. When the flexible printed circuit substrate 330 is connected to the terminal part 306, an external device and the display device 20 are connected via the flexible printed circuit substrate 330. Each pixel circuit 301 arranged in the display device 20 is driven by a signal from the external device input via the flexible printed circuit substrate 330.

The semiconductor device 10 described in the first embodiment is used as a switching element or a current control element included in the pixel circuit 301, the source driver circuit 302, and the gate driver circuit 303.

### [Pixel Circuit of Display Device]

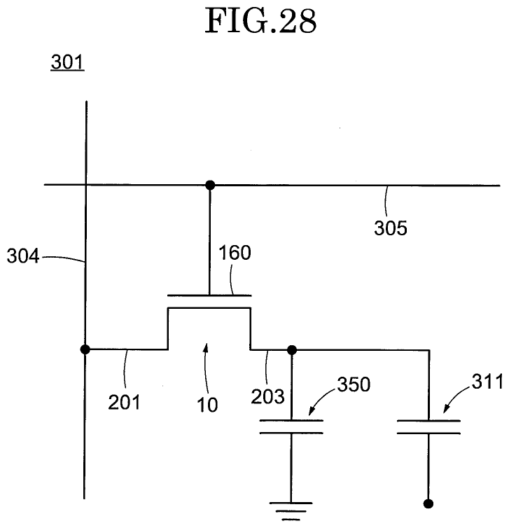

FIG. 28 is a circuit diagram showing a configuration of the pixel circuit 301 of the display device 20 according to an embodiment of the present invention. As shown in FIG. 28, the pixel circuit 301 includes elements such as the semiconductor device 10, a storage capacitor 350, and the liquid crystal element 311.

The semiconductor device 10 includes the gate wiring 160, the source wiring 201, and the drain wiring 203. The gate wiring 160 is connected to the scanning signal line 305. However, the gate wiring 160 and the scanning signal line 305 may be formed of an integral conductive layer. The source wiring 201 is connected to the data signal line 304. However, the source wiring 201 and the data signal line 304 may be formed of an integral conductive layer.

The drain wiring 203 is connected to the storage capacitor 350 and the liquid crystal element 311. In addition, the roles of the source wiring 201 and the drain wiring 203 may be changed depending on the relationship between the voltage supplied to the data signal line 304 and the voltage stored in the storage capacitor 350. That is, the source wiring 201 may function as a drain wiring and the drain wiring 203 may function as a source wiring.

### Fifth Embodiment

In the fourth embodiment, it has been described that the semiconductor device described in the first to third embodiments can be applied to the liquid crystal display device. However, the semiconductor device of the embodiments can also be applied to other display devices other than the liquid crystal display device. For example, the semiconductor device of the embodiments may be applied to a self-luminous display device such as an organic EL display device or an electronic paper display device.

Each of the embodiments (including modifications of the embodiments) described above as an embodiment of the present invention can be appropriately combined and implemented as long as no contradiction is caused. Furthermore, the addition, deletion, or design change of components, or the addition, deletion, or condition change of processes as appropriate by those skilled in the art based on each embodiment are also included in the scope of the present invention as long as they are provided with the gist of the present invention.

Furthermore, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
a first insulating layer;
an oxide semiconductor layer having a polycrystalline structure on the first insulating layer;
a gate insulating layer on the semiconductor oxide layer;
a buffer layer on the gate insulating layer;
a gate wiring on the buffer layer; and
a second insulating layer on the gate wiring, wherein
the oxide semiconductor layer has a first region, a second region and a third region aligned toward a first direction,
an electrical resistivity of the second region is higher than an electrical resistivity of the first region and lower than an electrical resistivity of the third region, and
a sheet resistance of the third region is less than 1000 ohm/square.

2. The semiconductor device according to claim 1 wherein
a thickness of the buffer layer is thinner than a thickness of the gate insulating layer.

3. The semiconductor device according to claim 1 wherein
the first region overlaps the gate wiring,
the second region overlaps the buffer layer and does not overlap the gate wiring, and
the third region does not overlap the buffer layer.

4. The semiconductor device according to claim 1 wherein
a distance from a top surface of the second region to a top surface of the second insulating layer is longer than a distance from a top surface of the third region to a top surface of the second insulating layer.

5. The semiconductor device according to claim 1 wherein
a length of the second region in the first direction is 0.1 μm or more and 1.5 μm or less.

6. The semiconductor device according to claim 1 wherein
the first region is a channel region,
the second region is an LDD region, and
the third region is a source region or a drain region.

7. The semiconductor device according to claim 1 further comprising:
a metal oxide layer between the first insulating layer and the oxide semiconductor layer.

8. The semiconductor device according to claim 7 wherein
the metal oxide layer is an oxide layer containing aluminum as a main component.

9. The semiconductor device according to claim 7 wherein
the metal oxide layer and the oxide semiconductor layer have the same pattern shape.

10. The semiconductor device according to claim 1 wherein
the oxide semiconductor layer contains at least two or more metallic elements including indium, and
a ratio of indium to the at least two or more metallic elements is 50% or more.

11. A semiconductor device comprising:
a first insulating layer;
an oxide semiconductor layer having a polycrystalline structure on the first insulating layer;
a gate insulating layer on the semiconductor oxide layer;
a buffer layer on the gate insulating layer;
a gate wiring on the buffer layer; and
a second insulating layer on the gate wiring, wherein
the oxide semiconductor layer has a first region, a second region and a third region aligned toward a first direction,
an electrical resistivity of the second region is higher than an electrical resistivity of the first region and lower than an electrical resistivity of the third region, and
an etching rate is less than 3 nm/min when the oxide semiconductor layer is etched using an etching solution containing phosphoric acid as the main component at 40° C.

12. The semiconductor device according to claim 11 wherein
a thickness of the buffer layer is thinner than a thickness of the gate insulating layer.

13. The semiconductor device according to claim 11 wherein
the first region overlaps the gate wiring,
the second region overlaps the buffer layer and does not overlap the gate wiring, and
the third region does not overlap the buffer layer.

14. The semiconductor device according to claim 11 wherein
a distance from a top surface of the second region to a top surface of the second insulating layer is longer than a distance from a top surface of the third region to a top surface of the second insulating layer.

15. The semiconductor device according to claim 11 wherein
a length of the second region in the first direction is 0.1 μm or more and 1.5 μm or less.

16. The semiconductor device according to claim 11 wherein
the first region is a channel region,
the second region is an LDD region, and
the third region is a source region or a drain region.

17. The semiconductor device according to claim 11 further comprising:
a metal oxide layer between the first insulating layer and the oxide semiconductor layer.

18. The semiconductor device according to claim 17 wherein
the metal oxide layer is an oxide layer containing aluminum as a main component.

19. The semiconductor device according to claim 17 wherein
the metal oxide layer and the oxide semiconductor layer have the same pattern shape.

20. The semiconductor device according to claim 11 wherein
the oxide semiconductor layer contains at least two or more metallic elements including indium, and
a ratio of indium to the at least two or more metallic elements is 50% or more.
